(19) United States
(12) Patent Application Publication
(10) Pub. No.: US 2018/0048283 A1
(43) Pub. Date: Feb. 15, 2018

(54) LITHIUM TANTALATE SINGLE CRYSTAL SUBSTRATE, BONDED SUBSTRATE, MANUFACTURING METHOD OF THE BONDED SUBSTRATE, AND SURFACE ACOUSTIC WAVE DEVICE USING THE BONDED SUBSTRATE

(71) Applicant: SHIN-ETSU CHEMICAL CO., LTD., Tokyo (JP)

(72) Inventors: Masayuki Tanno, Annaka-shi (JP); Jun Abe, Annaka-shi (JP); Koji Kato, Annaka-shi (JP); Yoshinori Kuwabara, Annaka-shi (JP); Kazutoshi Nagata, Annaka-shi (JP)

(73) Assignee: SHIN-ETSU CHEMICAL CO., LTD., Tokyo (JP)

(21) Appl. No.: 15/789,718

(22) Filed: Oct. 20, 2017

Related U.S. Application Data
(63) Continuation-in-part of application No. 15/566,247, filed on Oct. 13, 2017.

(30) Foreign Application Priority Data
Apr. 16, 2015 (JP) 2015-083941

(51) Int. Cl. H03H 9/02; C01G 33/00; H01L 41/187; H01L 41/257; B32B 18/00; C30B 29/30; C30B 31/02; C30B 33/02; C30B 33/06; C01G 35/00; H01L 41/335

(52) U.S. Cl. CPC H03H 9/02559; C01G 35/006; C01G 33/006; H01L 41/1873; H01L 41/257; H01L 41/335; C30B 29/30; C30B 31/02; C30B 33/02; C30B 33/06; B32B 18/00; H03H 9/25

(57) ABSTRACT

The lithium tantalate single crystal substrate is a rotated Y-cut LiTaO₃ single crystal substrate having a crystal orientation of 36° Y-49° Y cut characterized in that: the substrate is diffused with Li from its surface into its depth such that it has a Li concentration profile showing a difference in the Li concentration between the substrate surface and the depth of the substrate; and the substrate is treated with single polarization treatment so that the Li concentration is substantially uniform from the substrate surface to a depth which is equivalent to 5-15 times the wavelength of either a surface acoustic wave or a leaky surface acoustic wave propagating in the LiTaO₃ substrate surface.

### CROSS-REFERENCE TO RELATED APPLICATIONS

This is a continuation-in-part of U.S. Ser. No. 15/566,247, filed Oct. 13, 2017, which is a 371 of International Application No. PCT/JP2016/061226, filed Apr. 6, 2016, which is based upon and claims the benefits of priority to Japanese Application No. 2015-083941, filed Apr. 16, 2015. The entire contents of all of the above applications are incorporated herein by reference.

### TECHNICAL FIELD

The present invention relates to a lithium tantalate single crystal substrate, a bonded substrate thereof, a manufacturing method of the bonded substrate, and a surface acoustic wave device using such bonded substrate.

### BACKGROUND ART

A surface acoustic wave (SAW) device formed with a comb-like electrode (IDT: Interdigital Transducer) for exciting a surface acoustic wave on a piezoelectric substrate is used as a component for frequency adjustment and selection of a mobile phone or the like.

For this surface acoustic wave device, a piezoelectric material such as lithium tantalate (LiTaO₃ or LT) and lithium niobate (LiNbO₃ or LN) is used to make the base substrate, because piezoelectric materials meet the requirements of small size, small insertion loss, and ability to stop passage of unnecessary waves.

Now, on one hand, the communication standards for the fourth generation cellular phones call for a narrow difference in frequency band between transmission and reception as well as a wide bandwidth, but on the other hand, under such communication standards, unless the property changes induced by temperature change of the material of the surface acoustic wave device are sufficiently small, there occurs a shift in the frequency selection range, which results in problematic hindrance to the filter and duplexer functions of the device. Therefore, a material for a surface acoustic wave device having small tendency to undergo fluctuation in properties with respect to temperature change and having a wide band is eagerly called for.

Regarding such material for the surface acoustic wave device, for example, IP Document 1 teaches that a stoichiometric composition LT composed of copper used as an electrode material and commonly obtained by a gas phase method is preferable because the breakdown mode of sudden rupture at the moment when high power is input to the IDT electrode is hard to occur. Also, IP Document 2 has a detailed description on the stoichiometry composition LT obtained by the gas phase method; and likewise, IP Document 3 describes a detailed method of conducting an annealing upon a waveguide formed in a ferroelectric crystal of lithium tantalate or lithium niobate.

Further, IP Document 4 describes a piezoelectric substrate for a surface acoustic wave device obtained by subjecting a single crystal substrate of lithium tantalate or lithium niobate to Li diffusion treatment, and IP Document 5 and Non-IP Document 1 also report that, when LT in which the LT composition was uniformly transformed to be Li-rich from the surface to a depth by a gas phase equilibrium method was used to make the surface acoustic wave element, its frequency stability against temperature change was improved, hence preferable.

### PRIOR ART DOCUMENTS

### IP Publications

IP Publication 1: Japanese Patent Application Publication No. 2011-135245
IP Publication 2: U.S. Pat. No. 6,652,644 (B1)
IP Publication 3: Japanese Patent Application Publication No. 2003-207671
IP Publication 4: Japanese Patent Application Publication No. 2013-66032
IP Publication 5: WO2013/135886(A1)

### Non-IP Publications

Bartasyte, A. et. al, “Reduction of temperature coefficient of frequency in LiTaO₃ single crystals for surface acoustic wave applications” Applications of Ferroelectrics held jointly with 2012 European Conference on the Applications of Polar Dielectrics and 2012 International Symp Piezoresponse Force Microscopy and Nanoscale Phenomena in Polar Materials (ISAF/ECAPD/PFM), 2012 Intl Symp, 2012, Page(s): 1-3

### SUMMARY OF THE INVENTION

### Problems to be Solved by Invention

However, as the inventors of the present invention have examined the methods described in these publications, it has been found that these methods do not necessarily provide favorable results. In particular, according to the method described in IP Document 5, the wafer is processed at a high temperature of about 1300° C. in the vapor phase, and the manufacturing temperature also has to be as high as about 1300° C., so that the consequent warpage of the wafer would be large, and cracks can occur at a high rate, whereby the productivity becomes poor, and there is also a problem that the product becomes overly expensive as a material for a surface acoustic wave device. Moreover, in this manufacturing method, the vapor pressure of Li₂O is so low that the modification degree of the sample to be modified varies significantly depending on the distance from the Li source, and the resulting problem of fluctuation in quality of the product is making industrialization thereof obstructed.

Furthermore, in the manufacturing method described in IP Document 5, a single polarization treatment is not performed on the lithium-enriched LT after the modification by the gas phase equilibrium method, and as a result of exploration on this point by the present inventors, it was newly found that with the LT that is modified to be Li-rich but is not subjected to a single polarization treatment there occurs a problem that the value Q of the SAW device ends up small.

The present invention has been made in view of the above circumstances, and an object of the present invention is to provide a method for manufacturing a lithium tantalate single crystal substrate which incurs only small warpage, scarcely has cracks and scratches, undergoes smaller property changes with temperature than conventional rotated Y-cut LiTaO₃ substrates do, and renders a high electromechanical coupling coefficient and high values of Q in the device; the invention also seeks to provide a bonded substrate obtained by bonding the above-mentioned lithium tantalate single crystal substrates, a method for manufacturing the above mentioned bonded substrate, and eventually a surface acoustic wave device using such substrate.

As a result of extensive studies to achieve the above object, the present inventors came to find that it is possible to obtain a piezoelectric oxide single crystal substrate which, when employed as a surface acoustic wave element or the like, will incur only small warpage, have scarce cracks and scratches, and undergo reduced property changes with temperature without having to go so far as to modify the substrate to create a crystalline structure having a uniform Li concentration in a range extending close to the core of the substrate in the thickness direction, if the following procedure is conducted, namely, to apply vapor phase Li diffusion treatment to a substrate having a substantially congruent composition to thereby create in it such a modified area wherein the Li concentration profile as taken in the thickness direction shows a higher Li concentration at a measurement point closer to the surface of the substrate and a lower Li concentration at a measurement point closer to the core of the substrate. In addition, the inventors have found that the range of the modification by the Li diffusion as well as whether or not the single polarization treatment is conducted are liable to affect the value Q of the device, and hence they possessed the present invention.

Further, an object of the present invention is to provide a method for manufacturing a bonded substrate formed by bonding a substrate composed of a Li-containing compound to a base substrate by controlling a Li concentration, and to provide a new bonded substrate obtained using the manufacturing method.

Further, an object of the present invention is to provide a method for manufacturing a substrate composed of a Li-containing compound by controlling a Li concentration, and to provide a new substrate composed of a Li-containing compound obtained using the manufacturing method.

### Means for Solving the Problem

Therefore, the lithium tantalate single crystal substrate of the present invention is a rotated Y-cut LiTaO₃ single crystal substrate having a crystal orientation of 36° Y-49° Y cut characteristic in that: it received an Li diffusion from its surface into its depth with a result that the Li concentration profile shows a difference in Li concentration between the surface of the substrate and an inner part of the substrate; and it received a single polarization treatment with a result that Li concentration is roughly uniform from the surface of the substrate to a depth which is 5-15 times the wavelength of a surface acoustic wave or a leaky surface acoustic wave propagating in the LiTaO₃ substrate surface.

In the present invention it is preferable that the Li concentration profile shows that the Li concentration is higher at a point closer to the surface of the rotated Y-cut LiTaO₃ substrate and the Li concentration is lower at point closer to the core of the substrate, and that the ratio of Li to Ta at the surface of the substrate is such that: Li:Ta=50−α: 50+α, where α is in the range of −0.5<α<0.5. It is also preferable that Fe is doped in the substrate at a concentration of 25 ppm to 150 ppm.

In addition, the lithium tantalate single crystal substrate of the present invention can be bonded to a base substrate to form a bonded substrate. In that case, it is preferable to remove the LiTaO₃ surface layer from the surface opposite to the bonding surface in a manner such that at least a part of the portion in which the Li concentration is substantially uniform, to form a bonded substrate; also, the base substrate is preferably made of Si, SiC, or spinel. Furthermore, the method of manufacturing a bonded substrate according to the present invention is characterized in that a LiTaO₃ single crystal substrate having a substantially uniform Li concentration is bonded to a base substrate to thereby leave at least a part of the portion in which the Li concentration is substantially uniform, or that the LiTaO₃ surface layer is removed from the surface opposite to the bonding surface so as to leave only that portion in which the Li concentration is substantially uniform, and the method is also characteristic in that the said portion in which the Li concentration is substantially uniform is of a pseudo stoichiometric composition.

The lithium tantalate single crystal substrate and the bonded substrate of the present invention are suitable as a material for the surface acoustic wave device.

In the method of the present invention for manufacturing a bonded substrate, a substrate composed of a Li-containing compound having a concentration profile that shows a difference in Li concentration between a surface of the substrate and an inner part of the substrate is bonded to a base substrate, and a surface layer of the substrate composed of a Li-containing compound on an opposite side of a bonding surface is removed such that a portion of the substrate composed of a Li-containing compound remains.

A bonded substrate of the present invention includes: a substrate composed of a Li-containing compound; and a base substrate. In the bonded substrate, a Li concentration of a surface on a side of the substrate composed of a Li-containing compound exceeds 50.0 mol %.

Further, a bonded substrate includes: a substrate composed of a Li-containing compound; and a base substrate. In the bonded substrate, a Li concentration of a surface on a side of the substrate composed of a Li-containing compound exceeds 49.9 mol %, the substrate composed of a Li-containing compound has a thickness of 1.0 μm or less, and a maximum height (Rz) value of a surface roughness on the side of the substrate composed of a Li-containing compound is 10% or less of the thickness of the substrate composed of a Li-containing compound.

In a substrate composed of a Li-containing compound of the present invention, one surface of the substrate and the other surface of the substrate have different Li concentrations.

Further, a substrate composed of a Li-containing compound includes, in a thickness direction of the substrate: a first range where a Li concentration is substantially uniform from a bonding surface; a second range where a Li concentration varies from the bonding surface side toward a surface on an opposite side of the bonding surface; and a third range where a Li concentration is substantially uniform up to the surface on the opposite side of the bonding surface.

The present invention provides a method for manufacturing these substrates, each of which is composed of a Li-containing compound. In this method, a substrate composed of a Li-containing compound has a concentration profile that shows a difference in Li concentration between a surface of the substrate and an inner part of the substrate, and a portion of the substrate is removed such that an inner part of the substrate having a Li concentration different from that of a surface of the substrate becomes a surface of the substrate on one side.

Further, the present invention provides a method for manufacturing these substrates, each of which is composed of a Li-containing compound. In this method, a substrate composed of a Li-containing compound has, in a thickness direction of the substrate: a first range where a Li concentration is substantially uniform from one surface of the substrate; a second range where a Li concentration varies from a substrate surface side toward an inner part of the substrate; a third range where a Li concentration is substantially uniform; a fourth range where a Li concentration varies from an inner part of the substrate toward the other surface of the substrate; and a fifth range where a Li concentration is substantially uniform up to the other surface of the substrate, and the Li concentration of the third range is different from the Li concentrations of the first range and the fifth range, and a portion of the substrate composed of a Li-containing compound is removed in such a manner that an inner part of the third range becomes a surface of the substrate on one side.

Further, the present invention provides a method for manufacturing a bonded substrate, in which these substrates, each of which is composed of a Li-containing compound, are each bonded to a base substrate.

The present invention provides a bonded substrate that includes a substrate composed of a Li-containing compound, and a base substrate, and in which a Li concentration of a surface of the bonded substrate on a side of the substrate composed of a Li-containing compound is different from a Li concentration of a bonding surface of the substrate composed of a Li-containing compound.

Further, the present invention provides a bonded substrate that includes a substrate composed of a Li-containing compound, and a base substrate, and in which the substrate composed of a Li-containing compound includes, in a thickness direction of the substrate: a first range where a Li concentration is substantially uniform from a bonding surface; a second range where a Li concentration varies from the bonding surface side toward a surface on an opposite side of the bonding surface; and a third range where a Li concentration is substantially uniform up to the surface on the opposite side of the bonding surface.

### Effects of the Invention

According to the present invention, it is possible to provide a lithium tantalate single crystal substrate having better temperature non-dependency characteristics than the conventional rotated Y-cut LiTaO₃ substrates, having a large electromechanical coupling coefficient and having high values Q of the device. In addition, the surface acoustic wave device using this single crystal substrate can be provided at a low price and is suitable for a broadband band which is required for a smartphone.

Further, according to an object of the present invention, it is possible to provide a bonded substrate that is obtained by bonding a substrate, which is composed of a Li-containing compound and in which a Li concentration is controlled to a desired value, to a base substrate. As a result, it is possible to provide a new bonded substrate that cannot be obtained conventionally.

Further, it is possible to provide a substrate that is composed of a Li-containing compound and in which a Li concentration is controlled to a desired value. As a result, it is possible to provide a new substrate that is composed of a Li-containing compound and that cannot be obtained conventionally.

### BRIEF DESCRIPTION OF THE DRAWINGS

FIG. 1 A diagram showing a Raman profile of Example 1.

FIG. 2 A diagram showing an insertion loss waveform of the SAW filter of Example 1.

FIG. 3 A diagram showing SAW resonator waveforms of Example 1.

FIG. 4 A diagram showing values calculated by means of SAW resonator waveform, input impedance (Zin) real part/imaginary part display waveform and BVD model of Example 1.

FIG. 5 A diagram showing values calculated by means of measured values of SAW resonator input impedance (Zin) in the cases of Example 1 and Comparative Examples 2 and 4 and the calculated value in the case of BVD model, where the real part is taken on the horizontal axis and the imaginary part is taken on the vertical axis.

FIG. 6 A transmission electron microscopic photograph of a bonded substrate of Example 5 taken over an area of the interface between LiTaO₃ and Si.

FIG. 7 A graph illustrating a profile of a Li amount in a depth direction in an LT substrate of Example 7.

FIG. 8 A graph illustrating a profile of a Li amount in a depth direction in the LT substrate of Example 7.

### EMBODIMENTS FOR CARRYING OUT THE INVENTION

Hereinafter, embodiments of the present invention will be described in detail, but the present invention is not limited to these embodiments.

The lithium tantalate single crystal substrate of the present invention has a concentration profile in which the Li concentration is different between the substrate surface and an inner part of the substrate. It is preferable from the viewpoint of easiness in fabrication for the substrate to have a region in which the concentration profile is such that the Li concentration is higher in an area closer to the substrate surface in the thickness direction of the substrate and the Li concentration is lower in an area closer to the substrate core. Such a substrate having a region showing the above-described concentration profile of Li can be easily produced by diffusing Li from the substrate surface by any known method. Here, the “concentration profile” refers to a continuous (non-stepped) change in concentration.

The lithium tantalate single crystal substrate of the present invention is characteristic in that it has a substantially uniform Li concentration in a region between its surface and its depth which is 5-15 times the wavelength of a surface acoustic wave or a leaky surface acoustic wave propagating in the surface of the LiTaO₃ substrate. This is because a LiTaO₃ substrate having a region wherein Li concentration is substantially uniform ranging from the substrate surface to a depth equivalent to at least 5 times the wavelength of a surface acoustic wave or a leaky surface acoustic wave propagating in the surface of the LiTaO₃ substrate would show about the same or larger value of Q as compared with a LiTaO₃ substrate not subjected to Li diffusion treatment. If the region having substantially uniform Li concentration is set to have a depth exceeding 15 times the said wavelength, it takes unreasonably long time to diffuse Li, resulting in poor productivity, and in addition the longer time of Li diffusion is, the greater becomes the possibility for the substrate to incur a warpage or a crack.

The Li concentration of the lithium tantalate single crystal can be evaluated by measuring the Raman shift peak. With regard to lithium tantalate single crystals, it is known that a roughly linear relationship can be obtained between the half-value width of the Raman shift peak and the Li concentration, i.e., Li/(Li+Ta). [Ref. non-IP publication: 2012 IEEE International Ultrasonics Symposium Proceedings, page(s):1252-1255, Applied Physics A 56, 311-315 (1993)] Therefore, by using a formula representing such a relationship, it is possible to evaluate the composition at an arbitrary position of the oxide single crystal substrate.

A formula representing a relationship between the half-value width of the Raman shift peak and the Li concentration is obtained by measuring the Raman half-value width for some samples having a known composition and different Li concentrations; so long as the conditions of Raman measurement are the same, it will do to use a formula already disclosed in literature, etc. For example, for lithium tantalate single crystal, the following formula (1) may be used.

<Equation 1>

Li/(Li+Ta)=(53.15−0.5FWHM₁)/100 (1)

wherein, “FWHM1” is the half-value width of the Raman shift peak around 600 cm⁻¹; for details of measurement conditions, refer to any relevant publication.

For the purpose of the present invention “the region wherein the Li concentration is substantially uniform ranging from the substrate surface” means a region in which the Raman shift peak's half-value width around 600 cm⁻¹ is in the range of ±0.2 cm⁻¹ or so of that at the surface of the substrate or a region in which the value of Li/(Li+Ta) is in the range of ±0.001 (±0.1 mol %) or so of that at the surface of the substrate.

The lithium tantalate single crystal substrate of the present invention is characteristic in that it has received a single polarization treatment, for this treatment renders the value Q of the substrate greater than that in the case of a substrate without polarization treatment; it is preferable that this polarization treatment is conducted after the Li diffusion treatment.

Further, in the lithium tantalate single crystal substrate of the present invention, the ratio of Li to Ta at the substrate surface is preferably Li:Ta=50−α:50+α where α is in the range of −0.5<α<0.5. This is because if the ratio of Li to Ta at the surface of the substrate is within the above range, the substrate surface can be deemed to be of pseudo-stoichiometric composition, and exhibits particularly excellent temperature non-dependency characteristics.

The lithium tantalate single crystal substrate of the present invention can be produced, for example, by subjecting an oxide single crystal substrate having a substantially congruent composition to a vapor phase treatment for diffusing Li from the surface of the substrate to the inside thereof. The oxide single crystal substrates having a substantially congruent composition can be obtained by creating a single crystal ingot through a known method such as Czochralski method, slicing the ingot into wafers and, if necessary, lapping or polishing the wafers.

Further, the lithium tantalate single crystal substrate of the present invention may be doped with Fe at a concentration of 25 ppm to 150 ppm. This is because a lithium tantalate single crystal substrate doped with Fe at a concentration of 25 ppm to 150 ppm allows itself to be diffused with Li at rate about 20% faster than in the case of one doped with no Fe, and thus the productivity of the Li-diffused lithium tantalate wafer is substantially improved—hence the preference. As a procedure for effecting a doping of Fe in a lithium tantalate single crystal substrate, it is possible to add an appropriate amount of Fe₂O₃ to the raw material when raising a single crystal ingot by Czochralski method.

Furthermore, the polarization treatment to be carried out in the present invention may be performed by any known method, and as for the vapor phase treatment, although it is conducted in the examples below with the substrate buried in a powder consisting mainly of Li₃TaO₄, it should be construed that the invention is not limited to the kind or the form of the materials used in the vapor phase treatment in the examples. Further, as for the substrate subjected to the vapor phase treatment, additional processing and treatment may be carried out, if need be.

The lithium tantalate single crystal substrate of the present invention can be bonded to various base substrates to form a bonded substrate. The base substrate to which the inventive substrate is bonded is not particularly limited, and can be selected according to the purpose; but it is preferably one made of Si, SiC, or spinel.

Also, in the case of manufacturing the bonded substrate of the present invention, it is possible to remove the LiTaO₃ surface layer from the surface opposite to the bonding surface in a manner such that at least a part of the region in which the Li concentration is substantially uniform is left, so as to obtain a bonded substrate having excellent characteristics for a surface acoustic wave device.

The surface acoustic wave device manufactured using the lithium tantalate single crystal substrate or the bonded substrate of the present invention would have excellent temperature non-dependency characteristics and is particularly suitable as a component for a fourth generation mobile phone or the like.

The present invention provides a method for manufacturing a bonded substrate, in which a substrate composed of a Li-containing compound having a concentration profile that shows a difference in Li concentration between a surface of the substrate and an inner part of the substrate is bonded to a base substrate, and a surface layer of the substrate composed of a Li-containing compound on an opposite side of a bonding surface is removed such that a portion of the substrate composed of a Li-containing compound remains.

Here, the Li-containing compound is preferably a piezoelectric compound that can be used for a surface acoustic wave device. Examples of the Li-containing compound include lithium tantalate, lithium niobate, lithium tetraborate, and the like, and single crystals of these compounds can be used. When the Li-containing compound is a lithium tantalate single crystal, the single crystal preferably has a crystal orientation of a rotated 36° Y-49° Y cut.

Further, the base substrate can be selected from substrates of silicon, sapphire, silicon carbide, spinel and the like, and may be a laminated substrate containing these substances.

A method for bonding the substrate composed of a Li-containing compound to the base substrate is not particularly limited. The bonding may be performed using an adhesive or the like, and a direct bonding method such as a diffusion bonding method, a room temperature bonding method, a plasma activation bonding method, a surface activation room temperature bonding method, or the like can also be used. In this case, an interposing layer may be provided between a piezoelectric substrate and a support substrate.

For a piezoelectric substrate such as a lithium tantalate single crystal substrate or a lithium niobate single crystal substrate and a support substrate such as a silicon substrate or a sapphire substrate, a difference in thermal expansion coefficient is large. In order to suppress peeling, defects or the like, it is preferable to use a room temperature bonding method. However, the room temperature bonding method also has an aspect that a bonding system is limited. Further, in order to restore crystallinity of a piezoelectric layer, heat treatment may be necessary in some cases.

A surface activation treatment method in a surface activation bonding method is not particularly limited. However, an ozone water treatment, a UV ozone treatment, an ion beam treatment, a plasma treatment, or the like can be used.

Further, an interposing layer may be provided between a piezoelectric layer of a composite substrate and a support substrate. Although a material of the interposing layer is not particularly limited, it is preferably an inorganic material, and may include, for example, SiO2, SiO2±0.5, SiO2 doped with Ti, a-Si, p-Si, a-SiC, Al2O3 or the like as a main component. Further, as the interposing layer, a layer composed of multiple materials may be laminated.

As a method for removing a surface layer of the substrate composed of a Li-containing compound on an opposite side of the bonding surface, the surface layer can be mechanically removed by polishing and grinding. Further, by implanting ions into the substrate composed of a Li-containing compound, a portion to remain as a bonded substrate and a portion to be removed from the bonded substrate can be separated from each other.

In this case, a separation method is not particularly limited. For example, separation can be performed by heating to a temperature of 200° C. or less and applying a mechanical stress using a wedge or the like to one end of an ion implantation part.

In the process of implanting ions to the substrate composed of a Li-containing compound, the ions are implanted to an arbitrary depth of the piezoelectric substrate. In the later separation process of the piezoelectric substrate, the separation is performed at the ion implantation part. Therefore, the depth of the ion implantation in this process determines a thickness of a piezoelectric layer after the separation of the piezoelectric substrate. Therefore, the depth of the ion implantation is preferably equal to a targeted thickness of the piezoelectric layer of the composite substrate or slightly larger in consideration of polishing cost or the like. The depth of the ion implantation differs depending on a material, ion species, and the like, but can be adjusted by an ion acceleration voltage.

Further, the ion species used in the ion implantation process are not particularly limited as long as the ion species can disturb crystallinity of a material of the piezoelectric substrate. However, the ion species are preferably light elements such as hydrogen ions, hydrogen molecular ions, or helium ions. When these ion species are used, there are advantages such as that ion implantation can be performed with a small acceleration voltage, that there are few restrictions on a device, that there is less damage to the piezoelectric substrate, and that distribution in a depth direction is good.

Here, when the ion species used in the ion implantation process are hydrogen ions, a dose amount of the hydrogen ions is preferably 1×1016−1×1018 atm/cm2. When the ion species are hydrogen molecular ions, a dose amount of the hydrogen molecular ions is preferably 1×1016−2×1018 atm/cm2. Further, when the ion species are helium ions, a dose amount of the helium ions is preferably 2×1016−2×1018 atm/cm2.

It is preferable that the substrate composed of a Li-containing compound have, in a thickness direction of the substrate: a first range where a Li concentration is substantially uniform from one surface of the substrate; a second range where a Li concentration varies from a substrate surface side toward an inner part of the substrate; and a third range where a Li concentration is substantially uniform, and the first range and the third range have different Li concentrations.

Further, it is preferable that the substrate composed of a Li-containing compound have, in the thickness direction of the substrate: a first range where a Li concentration is substantially uniform from one surface of the substrate; a second range where a Li concentration varies from a substrate surface side toward an inner part of the substrate; a third range where a Li concentration is substantially uniform; a fourth range where a Li concentration varies from an inner part of the substrate toward the other surface of the substrate; and a fifth range where a Li concentration is substantially uniform up to the other surface of the substrate, and the Li concentration of the third range be different from the Li concentrations of the first range and the fifth range.

Such a substrate composed of a Li-containing compound is obtained by diffusing Li from a surface of the substrate to the inside of the substrate. For example, for a substrate composed of a Li-containing compound of a congruent composition, by diffusing Li from a surface of the substrate to inside of the substrate and adjusting a reaction time and a reaction temperature, a substrate can be obtained in which a surface has a pseudo stoichiometric composition and the inside has a congruent composition.

When Li is diffused from both sides of the substrate, a substrate is obtained that has, in the thickness direction of the substrate: a first range where a Li concentration is substantially uniform from one surface of the substrate; a second range where a Li concentration varies from a substrate surface side toward an inner part of the substrate; a third range where a Li concentration is substantially uniform; a fourth range where a Li concentration varies from an inner part of the substrate toward the other surface of the substrate; and a fifth range where a Li concentration is substantially uniform up to the other surface of the substrate, and in which the Li concentration of the third range is different from the Li concentrations of the first range and the fifth range.

In this case, the Li concentrations of the first range and the fifth range are higher than the Li concentration of the third range. That is, the surfaces of the substrate have higher Li concentrations than an inner part of the substrate, and the Li concentration in each of the second range and the fourth range is higher on a substrate surface side.

Further, when Li is diffused from one side of the substrate, a substrate composed of a Li-containing compound is obtained in which a Li concentration of one surface of the substrate is different from a Li concentration of the other surface of the substrate. More specifically, a substrate is obtained that has, in a thickness direction of the substrate: a first range where a Li concentration is substantially uniform from one surface of the substrate; a second range where a Li concentration varies from a substrate surface side toward an inner part of the substrate; and a third range where a Li concentration is substantially uniform up to the other surface of the substrate, and in which the first range and the third range have different Li concentrations.

Such as a substrate can also be obtained by removing a portion of a substrate that has, in the thickness direction of the substrate: a first range where a Li concentration is substantially uniform from one surface of the substrate; a second range where a Li concentration varies from a substrate surface side toward an inner part of the substrate; a third range where a Li concentration is substantially uniform; a fourth range where a Li concentration varies from an inner part of the substrate toward the other surface of the substrate; and a fifth range where a Li concentration is substantially uniform up to the other surface of the substrate, and in which the Li concentration of the third range is different from the Li concentrations of the first range and the fifth range, the portion being removed in such a manner that an inner part of the third range becomes a surface of the substrate on one side.

In the substrate as described above, the first range or the fifth range is preferably a pseudo stoichiometric composition, and the third range is preferably a congruent composition. Further, the first range or the fifth range preferably has a Li concentration exceeding 50.0 mol %.

In this way, a bonded substrate containing a Li-containing compound of a pseudo stoichiometric composition having excellent characteristics can be formed. Further, it becomes possible to fabricate a bonded substrate in which a surface on a side of a substrate composed of a Li-containing compound or the entire substrate has a Li concentration exceeding 50.0 mol %, which is impossible by merely bonding a substrate composed of a Li-containing compound such as a LiTaO3 substrate of a stoichiometric (pseudo-stoichiometric) composition (Li/Li+Ta=49.95-50.0 mol %).

Therefore, the Li-containing compound to remain as a bonded substrate is preferably a pseudo stoichiometric composition.

Further, the Li-containing compound to remain as a bonded substrate preferably includes the first range or the fifth range, and preferably is the first range or the fifth range. Further, the first range or the fifth range preferably has a pseudo stoichiometric composition.

Here, the first range or the fifth range is a range where the Li concentration is continuously ±0.1% from a surface of the substrate. When the Li concentration decreases from a surface of the substrate, a range from a surface of the substrate to a point where the Li concentration becomes −0.1% can be the first range or the fifth range.

A “pseudo stoichiometric composition” is judged based on technical common senses depending on a material. However, in the case of lithium tantalate, the term “pseudo stoichiometric composition” refers to a composition of which a ratio of Li to Ta is Li:Ta=50−α:50+α, where α is in a range of −0.5<α<0.5. In the case of lithium niobate, a ratio of Li to Nb is Li:Nb=50−α:50+α, where α is in a range of −0.5<α<0.5.

A “congruent composition” is judged based on technical common senses depending on a material. However, in the case of lithium tantalate, the term “congruent composition” refers to a composition of which a ratio of Li to Ta is Li:Ta=48.5−α: 48.5+α, where α is in a range of −0.5<α<0.5.

According to the present invention, a bonded substrate can be manufactured that includes a substrate composed of a Li-containing compound, and a base substrate, and in which a Li concentration of a surface of the bonded substrate on a side of the substrate composed of a Li-containing compound is different from a Li concentration of a bonding surface of the substrate composed of a Li-containing compound. More specifically, a bonded substrate can be manufactured that includes a substrate composed of a Li-containing compound, and a base substrate, and in which the substrate composed of a Li-containing compound includes, in a thickness direction of the substrate: a first range where a Li concentration is substantially uniform from a bonding surface; a second range where a Li concentration varies from the bonding surface side toward a surface on an opposite side of the bonding surface; and a third range where a Li concentration is substantially uniform up to the surface on the opposite side of the bonding surface.

Such a bonded substrate can be obtained, for example, by bonding, to a base substrate, a substrate that has, in a thickness direction of the substrate as described above: a first range where a Li concentration is substantially uniform from one surface of the substrate; a second range where a Li concentration varies from a substrate surface side toward an inner part of the substrate; a third range where a Li concentration is substantially uniform; a fourth range where a Li concentration varies from an inner part of the substrate toward the other surface of the substrate; and a fifth range where a Li concentration is substantially uniform up to the other surface of the substrate, and in which the Li concentration of the third range is different from the Li concentrations of the first range and the fifth range, and by removing a portion ranging from a surface of the substrate on an opposite side of a bonding surface up to the third range.

Or, such a bonded substrate can also be obtained by bonding, to a base substrate, a substrate composed of a Li-containing compound, as fabricated above, in which a Li concentration of one surface of the substrate is different from a Li concentration of the other surface of the substrate, or, a substrate that has, in a thickness direction of the substrate: a first range where a Li concentration is substantially uniform from one surface of the substrate; a second range where a Li concentration varies from a substrate surface side toward an inner part of the substrate; and a third range where a Li concentration is substantially uniform up to the other surface of the substrate, and in which the first range and the third range have different Li concentrations.

In this way, the Li concentration of either one of the surface of the bonded substrate on the side of the substrate composed of a Li-containing compound and the bonding surface of the substrate composed of a Li-containing compound can be arbitrarily increased according to an intended purpose.

However, in a method for manufacturing a bonded substrate involving ion implantation, it is possible to control a thickness of the substrate composed of a Li-containing compound to 1.0 m or less and a surface roughness in terms of a maximum height (Rz) value to 10% or less of the thickness. It is preferable to control the thickness to 0.8 μm or less and the surface roughness in terms of the maximum height (Rz) value to 5% or less of the thickness. The control of the film thickness and the uniformity at this level is difficult in a method of polishing and grinding a bonded substrate composed of a Li-containing compound.

However, for example, when a LiTaO3 substrate is subjected to ion implantation and is then separated, some of the Li ions in the LiTaO3 substrate are pushed out by the implanted ions such as H+ ions. Therefore, it has been found that there is a problem that a Li amount of the LiTaO3 substrate that forms a bonded substrate is decreased.

In this case, since the Li amount of the LiTaO3 substrate is decreased, performance of LiTaO3 as a piezoelectric material is deteriorated. For example, when a composite substrate is fabricated involving ion implantation using a LiTaO3 substrate of a congruent composition (Li/Li+Ta=48.5 mol %) as a piezoelectric substrate, the Li amount decreases to 48.5 mol % or less.

Further, even when a LiTaO3 substrate of a stoichiometric (pseudo-stoichiometric) composition (Li/Li+Ta=49.95-50.0 mol %) fabricated using a double crucible method or the like is used as a piezoelectric substrate, the Li amount is decreased by at least about 0.1 mol % to 49.9 mol % or less.

Therefore, conventionally, it was not possible to obtain a composite substrate that includes a LiTaO3 substrate of a composition of which a Li concentration exceeds 49.9 mol % and that has a small thickness and excellent film thickness uniformity, which cannot be obtained using a fabrication method based on polishing and grinding.

In the present invention, when a portion to remain as a bonded substrate and a portion to be removed from the bonded substrate are separated from each other by implanting ions into the substrate composed of a Li-containing compound, a Li concentration at a position where the ions are implanted into the substrate composed of a Li-containing compound preferably exceeds 50.0 mol %, and a Li concentration from a surface of the substrate composed of a Li-containing compound on a side where the substrate composed of a Li-containing compound is bonded to the base substrate to the position where the ions are implanted into the substrate composed of a Li-containing compound preferably exceeds 50.0 mol %.

Further, the Li concentration is more preferably 50.05 mol % or more, and even more preferably 50.1 mol % or more. In this way, even when the Li concentration is decreased due to ion implantation, the Li concentration of the substrate composed of a Li-containing compound can exceed 49.9 mol %, and excellent characteristics can be obtained.

The Li concentration at the position where the ions are implanted into the substrate composed of a Li-containing compound is preferably 52.5 mol % or less, more preferably 51.0 mol % or less, and even more preferably 50.5 mol % or less.

By implanting ions into a piezoelectric substrate, piezoelectricity of a portion where the ions pass through may be impaired. However, in this way, the piezoelectricity is unlikely to be impaired, and piezoelectricity can be achieved even without performing a piezoelectricity recovery process.

Further, the present inventors have found that the Li concentration of the substrate composed of a Li-containing compound correlates with a decrease in the Li concentration due to ion implantation. That is, an amount of decrease in Li concentration when ions are implanted into a substrate composed of a Li-containing compound of a pseudo stoichiometric composition is smaller than an amount of decrease in Li concentration when ions are implanted into a substrate composed of a Li-containing compound of a congruent composition. That is, in the case of a substrate composed of a Li-containing compound of a congruent composition, a decrease of about 0.4 mol % is observed. However, in the case of a substrate composed of a Li-containing compound of a pseudo stoichiometric composition, a decrease of about 0.1 mol % is observed, and variation is also small.

According to the present invention, a bonded substrate that was conventionally impossible can be fabricated in which a Li concentration of a surface of a Li-containing compound exceeds 49.9 mol %, a substrate composed of a Li-containing compound has a thickness of 1.0 ii m or less, and a maximum height (Rz) value of a surface roughness of the substrate composed of a Li-containing compound is 10% or less of the thickness of the substrate composed of a Li-containing compound.

The Li concentration of the surface of the substrate composed of a Li-containing compound is preferably 49.95 mol % or more and 52.0 mol % or less. Further, the Li concentration of the entire substrate composed of a Li-containing compound preferably exceeds 49.9%. Further, the thickness of the substrate composed of a Li-containing compound is preferably 0.8 μm or less, and more preferably 0.6 μm or less. The maximum height (Rz) value of the surface roughness of the substrate composed of a Li-containing compound is preferably 5% or less, and more preferably 1% or less of the thickness of the substrate composed of a Li-containing compound.

The maximum height (Rz) is a parameter defined in JIS B 0601:2013 (ISO 4287:1997) and can be measured based on these standards.

### EXAMPLES

Hereinafter, examples of the present invention and comparative examples will be described more specifically.

### Example 1

In Example 1, at first, a singly polarized 4-inch diameter lithium tantalate single crystal ingot having a substantially congruent composition and having a Li:Ta ratio of 48.5:51.5 was sliced to obtain a number of 370-μm-thick 42° rotated Y-cut lithium tantalate substrates. Thereafter, in view of a protocol, the surface roughness of each sliced wafer was adjusted to 0.15 μm in terms of arithmetic average roughness value Ra by a lapping step, and the finished thickness was set to 350 μm (micrometer).

Subsequently, both side surfaces of the substrates (wafers) were finished into a quasi-mirror finish having an Ra value of 0.01 μm by planar polishing, and the substrates were buried in a powder composed of Li, Ta and O, mainly consisting in the form of Li₃TaO₄. The power consisting mainly in the form of Li₃TaO₄ which was used in this example was prepared by mixing Li₂CO₃ and Ta₂O₅ powders in a molar ratio of 7:3 in this order and subjecting the thus obtained mixture to a calcination at 1300° C. for 12 hours. The powder consisting mainly in the form of Li₃TaO₄ was spread in a small container, and a plurality of slice wafers were buried in the Li₃TaO₄ powder.

Then, this small container was set in an electric furnace and the inside of the furnace was replaced by an N₂ atmosphere before the furnace was electrified to heat at 975° C. for 100 hours whereupon Li diffused from the surface of the sliced wafer toward the middle part thereof. Thereafter, while the temperature of the wafer was allowed to lower, a 12-hour annealing treatment at 800° C. was applied to the wafer; then as the temperature went down from 770° C. to 500° C., an electric field of approximately 4000 V/m was applied in a substantially +Z direction; and thereafter the temperature was let to fall to the room temperature. After this treatment, one side of the wafer was subjected to a finishing work consisting of sandblasting whereby this side's Ra value became about 0.15 μm; on the other hand, the other quasi-mirror finish surface was subjected to a 3 μm polishing and in this manner a plurality of lithium tantalate single crystal substrates were made.

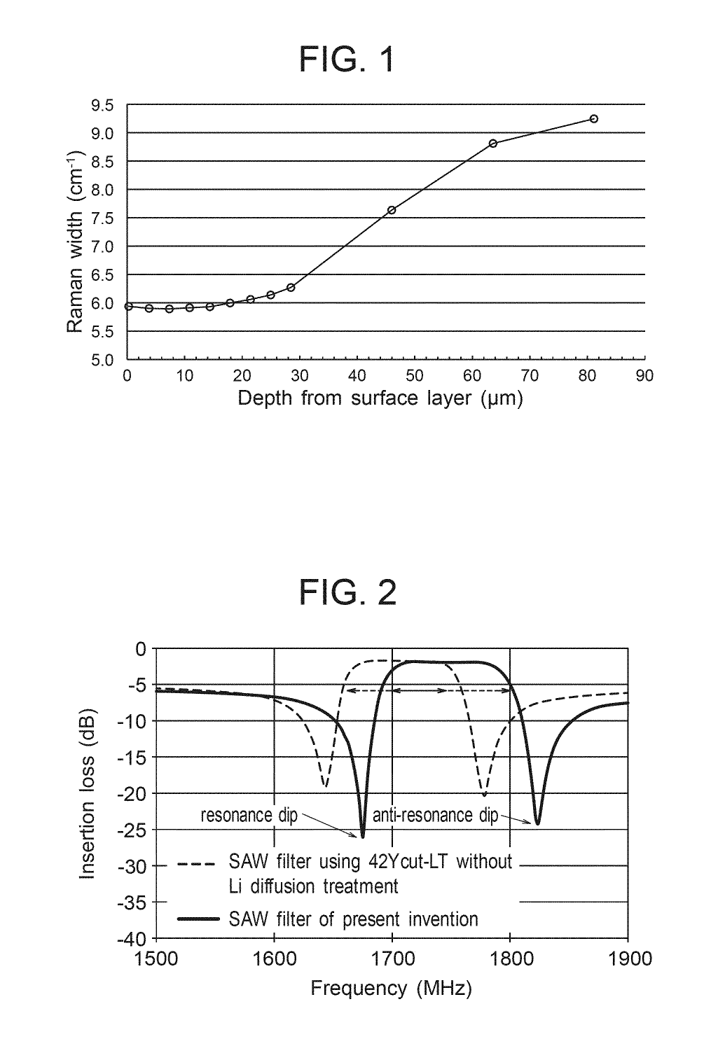

With regard to one of these lithium tantalate single crystal substrates, a laser Raman spectrometer (LabRam HR series manufactured by HORIBA Scientific Inc., Ar ion laser, spot size 1 μm, room temperature) was used to measure the half-value width of the Raman shift peak around 600 cm⁻¹, which is an indicator of the Li diffusion amount, with respect to a depth-wise distance from the surface at an arbitrarily chosen site which was 1 cm or more away from the outer circumference of the circular substrate; and as the result a Raman profile as shown in FIG. 1 was obtained.

According to the result of the profile shown in FIG. 1, while the value of the Raman half-value width at the surface of this lithium tantalate single crystal substrate differed from that in an in-depth part of the substrate, the value of the Raman half-value width was more or less constant, namely between 5.9 and 6.0 cm′ in the area of the depth from 0 μm through about 18 μm in the thickness direction. In the deeper area, it was confirmed that the value of the Raman half-value width tended to increase as the measuring point moved closer to the middle of the substrate.

The Raman half-value width at a depth of 80 μm in the thickness direction of the lithium tantalate single crystal substrate was 9.3 cm′, and although not shown in the figure, the Raman half-value width at the thickness-wise middle position of the substrate was also 9.3 cm′.

From the above results of FIG. 1 it was confirmed that in Example 1 the Li concentration in the vicinities of the substrate surface and that inside the substrate are different and that the substrate has a region which exhibits a concentration profile such that the Li concentration is higher in areas closer to the substrate surface, and the Li concentration decreases with depth of the substrate in the thickness direction. It was also confirmed that the Li concentration was roughly uniform up to the depth of 18 μm from the LiTaO₃ substrate surface.

Further, from the results of FIG. 1, the Raman half-value width is about 5.9-6.0 cm⁻¹ from the surface of the lithium tantalate single crystal substrate through to the depth of 18 μm in the thickness direction, wherefore, using the equation (1), the composition in that range is roughly Li/(Li+Ta)=0.515 through 0.52, so it was confirmed that the composition there was pseudo-stoichiometric.

Further, since the Raman half-value width at the middle portion in the thickness direction of the substrate of the lithium tantalate single crystal is about 9.3 cm⁻¹, when, similarly as above, the formula (1) is adopted, the value of Li/(Li+Ta) becomes 0.485, wherefore it was confirmed that the middle portion of the substrate was of a substantially congruent composition.

As described above, in the case of the rotated Y-cut LiTaO₃ substrate of Example 1, the region between the surface of the substrate and the position at which the Li concentration starts decreasing as well as the region between the position at which the Li concentration stops increasing and the other side surface of the substrate are of a pseudo-stoichiometric composition, and the middle part in the thickness direction is of a substantially congruent composition. The position at which the Li concentration starts decreasing or the position at which the Li concentration stops increasing were at a position of 20 μm from the substrate surface in the thickness direction, respectively.

Next, warping of this 4-inch lithium tantalate single crystal substrate subjected to Li diffusion was measured by interference measuring method using a laser light, and the value was as small as 60 μm, and chipping and crack were not observed.

Next, a small piece was cut out from the Li-diffused 4-inch 42° rotated Y cut lithium tantalate single crystal substrate, and, in a Piezo d33/d15 meter (model ZJ-3BN) manufactured by The Institute of Acoustics of the Chinese Academy of Sciences, the small piece was given a vertical vibration in the thickness direction to the principal face and also to the back face respectively to observe the voltage waveform thereby induced, and a waveform was observed at every position all over the wafer which indicated a presence of piezoelectric response. Hence it was confirmed that the lithium tantalate single crystal substrate of Example 1 has piezoelectricity at every site on the substrate surface, and thus can be used as a singly polarized surface acoustic wave device.

Next, a 42° Y-cut lithium tantalate single crystal substrate of Example 1 which had been subjected to the Li diffusion treatment was exposed to a sputtering treatment to receive on its surface an Al film having a thickness of 0.2 urn, and a resist material was applied to the thus treated substrate; then, a one-stage ladder type filter and an electrode pattern for a resonator were exposed and developed in a stepper, and an electrode for a SAW device was produced by means of RIE (Reactive Ion Etching).

Now, one wavelength of this patterned one-stage ladder type filter electrode was set to 2.33 m in the case of the series resonator and one wavelength of the parallel resonator was set to 2.47 g m. Furthermore, an evaluation-purpose single resonator was configured to have a wavelength of 2.50 μm.

With regard to this one-stage ladder type filter, the SAW waveform characteristic was explored by means of an RF prober, and the results shown in FIG. 2 were obtained. In FIG. 2, for the sake of comparison, the results of measurement of the SAW waveform in the case of a 42° Y-cut lithium tantalate single crystal substrate which was not subjected to Li diffusion treatment and was formed with a similar electrode as that described above are also shown in FIG. 2.

From the results shown in FIG. 2, in the SAW filter made of a 42° Y-cut lithium tantalate single crystal substrate subjected to Li diffusion treatment, the frequency span at which the insertion loss is 3 dB or less was confirmed to be 93 MHz, and the center frequency to be 1745 MHz. On the other hand, in the SAW filter made of a 42° Y-cut lithium tantalate single crystal substrate not subjected to Li diffusion treatment, the frequency span at which the insertion loss is 3 dB or less was 80 MHz, and the center frequency was 1710 MHz.

Also, while changing the temperature of the stage from about 16° C. to 70° C., the anti-resonance frequency corresponding to the frequency on the right side of the dip in FIG. 2 and the temperature coefficient of the resonance frequency corresponding to the frequency on the left side of the dip were examined and, as the result, since the temperature coefficient of the resonance frequency was −21 ppm/° C. and the temperature coefficient of the anti-resonance frequency was −42 ppm/° C., it was confirmed that the average frequency temperature coefficient was −31.5 ppm/° C. For comparison, the temperature coefficient of the 42° Y-cut lithium tantalate single crystal substrate not subjected to the Li diffusion treatment was also examined and, as the result, since the temperature coefficient of the resonance frequency was −33 ppm/° C. and the temperature coefficient of the anti-resonance frequency was −43 ppm/° C., the average frequency temperature coefficient was confirmed to be −38 ppm/° C.

Therefore, from the above results, it was confirmed that in the lithium tantalate single crystal substrate of Example 1, the band in which the insertion loss of the filter was 3 dB or less was 1.2 times wider as compared with the substrate not subjected to the Li diffusion treatment. With regard to the temperature-dependency characteristics as well, the average frequency temperature coefficient was about 6.5 ppm/° C. lower than that of the substrate not subjected to the Li diffusion treatment, so that the property fluctuation with temperature is small and thus the stability against temperature change was confirmed to be good.

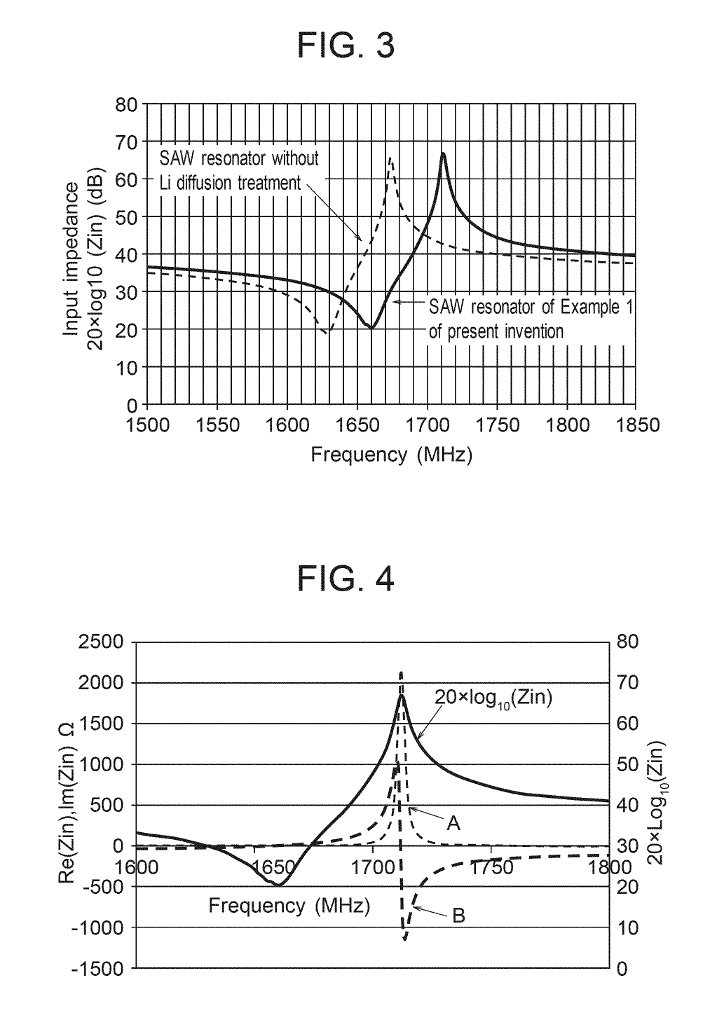

Next, a 1-port SAW resonator with a wavelength of 2.5 μm was fabricated from a 42° Y-cut lithium tantalate single crystal substrate subjected to the Li diffusion treatment of Example 1, and the SAW waveform shown in FIG. 3 was obtained. In FIG. 3, for the sake of comparison, a similar 1-port SAW resonator was also fabricated from a 42° Y-cut lithium tantalate single crystal substrate not subjected to Li diffusion treatment, and the results in the case of the thus obtained SAW waveforms are also shown in the figure.

From the results of the SAW waveforms of FIG. 3, the values of the anti-resonance frequency and the resonance frequency were obtained, and the electromechanical coupling coefficient k 2 was calculated based on the following Equation 2; as shown in Table 1, in the case of the 42° Y-cut lithium tantalate single crystal substrate subjected to the Li diffusion treatment of Example 1, the electromechanical coupling coefficient k2 was 7.7%, and this was about 1.2 times greater than that in the case of the 42° Y-cut lithium tantalate single crystal substrate not subjected to Li diffusion treatment.

Equation to obtain K²:

K²=(πfr/2fa)/tan(πfr/2fa) <Equation 2>

Wherein fr is resonance frequency and fa is anti-resonance frequency.

FIG. 4 shows, with respect to the SAW resonator of Example 1, the relationship between the real/imaginary parts of the input impedance (Zin) and the frequency, and also FIG. 4 shows the calculated value of the input impedance obtained by using the following equation (3) according to the BVD model (ref. John D. et al., “Modified Butterworth-Van Dyke Circuit for FBAR Resonators and Automated Measurement System”, IEEE ULTRASONICS SYMPOSIUM, 2000, pp. 863-868).

From the results of the graph curves A and B in FIG. 4, it was confirmed that the input impedance value measured in Example 1 well agrees with the calculated value in accordance with the BVD model.

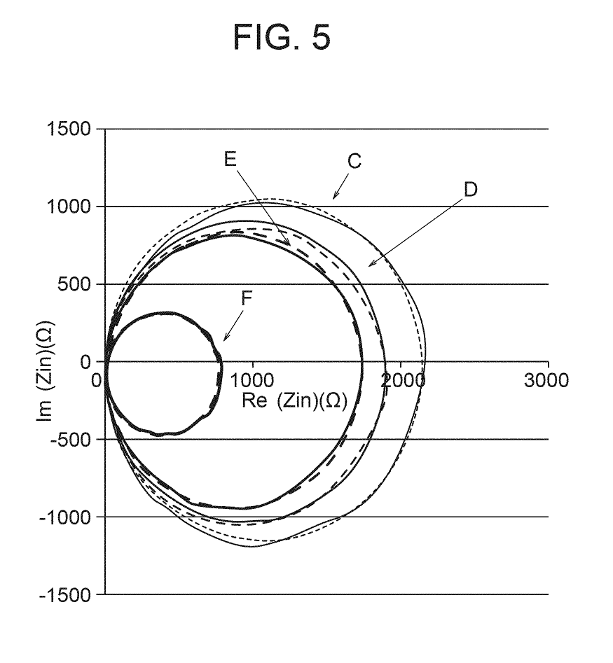

Further, Table 1 shows the results of value Q as calculated using the following formula (3), and FIG. 5 shows the measured values of the Q circle of the SAW resonator together with the calculated values in accordance with the BVD model.

Now, in the Q circle, the real part of the input impedance (Zin) is plotted against the horizontal axis and the imaginary part of the input impedance (Zin) is plotted against the vertical axis.

From the result of the Q circle curve C in FIG. 5, it was confirmed that the value of the input impedance measured in Example 1 and the value calculated in accordance with the BVD model are in good agreement, so that the values of Q obtained by means of Equation (3), shown below, in accordance with the BVD model can be said reasonable values. Further, in the Q circle, it can be judged that if the radius is roughly large, the value of Q is also large.

In addition, in Table 1 and FIG. 5, for the sake of comparison, the results in the case of a 42° Y-cut lithium tantalate single crystal substrate not subjected to Li diffusion treatment (see the Q circle of curve D in FIG. 5) are also shown, and it was confirmed that the Q of Example 1 shows a value equal to or even higher than the Q of the 42° Y-cut lithium tantalate single crystal substrate not subjected to Li diffusion treatment.

$$z ( ω ) = \frac{Xp}{j \cdot ( \frac{ω}{{ω}_{p}} )} \cdot \frac{[ 1 - {( \frac{ω}{ω s} )}^{2} + j \cdot ( \frac{ω}{ω s} ) \cdot \frac{1}{Qso} ]}{[ 1 - {( \frac{ω}{{ω}_{p}} )}^{2} + j \cdot ( \frac{ω}{{ω}_{p}} ) \frac{1}{Qpo} ]} \qquad 〈 Equation 3 〉$$

where:
where:

$$r = \frac{{C}_{0}}{{C}_{1}}$$

$$ω s = \frac{1}{\sqrt{{L}_{1} \cdot {C}_{1 }}}$$

$${( \frac{ω p}{{ω}_{s}} )}^{2} = 1 + \frac{1}{r}$$

$${X}_{p} = \frac{1}{ω p \cdot {C}_{0}}$$

$$\frac{1}{{Q}_{s}} = {ω}_{s} \cdot R 1 \cdot C 1$$

$$\frac{1}{Qe} = \frac{{ω}_{s} \cdot {R}_{0} \cdot {C}_{0}}{r}$$

$$\frac{1}{Qso} = \frac{1}{Qs} \cdot ( 1 + \frac{{R}_{s}}{{R}_{1}} )$$

$$\frac{1}{{Q}_{po}} = ( \frac{{ω}_{p}}{ω s} ) \cdot ( \frac{1}{Qs} + \frac{1}{Qc} )$$

### Example 2

In Example 2, first, by means of the same method as in Example 1, a lithium tantalate single crystal substrate having a roughly uniform Li concentration in a region from the surface of the substrate to a depth of 18 μm was prepared. Next, the surface of the substrate was lapped to a depth of 2 μm, whereby a lithium tatalate single crystal substrate having a roughly uniform Li concentration in a region from the surface of the substrate to a depth of 16 μm was obtained.

Then, the thus obtained lithium tantalate single crystal substrate was evaluated in the same manner as in Example 1, and the results are shown in Table 1. When normalized with the wavelength of the leaky surface acoustic wave propagating in the direction X of the wafer, the region in which the Li concentration is uniform ranged from the substrate surface to a depth equivalent to 6.4 times the wavelength.

As compared with the 42° Y-cut lithium tantalate single crystal substrate to which Li diffusion treatment is not subjected, the lithium tantalate single crystal substrate of Example 2 had a larger electromechanical coupling coefficient k2, a better temperature non-dependency characteristic, and the values Q which were similar to or in average greater than those of the former.

### Example 3

Also in Example 3, first, a lithium tantalate single crystal substrate having a region in which the Li concentration is substantially uniform from the substrate surface to a depth of 18 μm was prepared in the same manner as in Example 1. Next, the surface of the substrate was lapped to a depth of 4 μm, whereby a lithium tatalate single crystal substrate having a roughly uniform Li concentration in a region from the surface of the substrate to a depth of 14 μm was obtained.

Then, when the obtained lithium tantalate single crystal substrate was evaluated in the same manner as in Example 1, the results were as shown in Table 1. Also, when normalized with the wavelength of the leaky surface acoustic wave propagating in the direction X of the wafer, the region in which the Li concentration is uniform ranged from the substrate surface to a depth equivalent to 5.6 time the wavelength.

As compared with the 42° Y-cut lithium tantalate single crystal substrate to which Li diffusion treatment is not subjected, the lithium tantalate single crystal substrate of Example 3 had a larger electromechanical coupling coefficient k², better temperature non-dependency characteristic, and the values of Q which were similar to or in average greater than those of the former.

### Example 4

Also in Example 4, first, a lithium tantalate single crystal substrate having a region in which the Li concentration is substantially uniform from the substrate surface to a depth of 18 μm was prepared in the same manner as in Example 1. Next, the surface of the substrate was lapped to a depth of 5.5 μm, whereby lithium tatalate single crystal substrates having a roughly uniform Li concentration in a region from the surface of the substrate to a depth of 12.5 μm was obtained.

Then, when the obtained lithium tantalate single crystal substrate was evaluated in the same manner as in Example 1, the results were as shown in Table 1. Also, when normalized with the wavelength of the leaky surface acoustic wave propagating in the direction X of the wafer, the region in which the Li concentration is uniform ranged from the substrate surface to a depth equivalent to 5.0 times the wavelength.

As compared with the 42° Y-cut lithium tantalate single crystal substrate to which Li diffusion treatment is not subjected, the lithium tantalate single crystal substrate of Example 4 had a larger electromechanical coupling coefficient k2, better temperature non-dependency characteristic, and the values Q which were similar to or in average greater than those of the former.

### Example 5

In Example 5, first, a lithium tantalate single crystal substrate having a region in which the Li concentration is substantially uniform ranging from the substrate surface to a depth of 18 g m was prepared in the same manner as in Example 1. Next, this substrate and a 200-μm-thick Si substrate were bonded together by means of an ordinary temperature bonding method described in the non-IP publication [Takagi H. et al, “Room-temperature wafer bonding using argon beam activation” From Proceedings-Electrochemical Society (2001), 99-35 (Semiconductor Wafer Bonding: Science, Technology, and Applications V), 265-274.], and a bonded substrate was fabricated. Specifically, a cleansed substrate was set in a high-vacuum chamber and an activation treatment was performed upon the substrate by irradiating a high speed atomic beam of argon in which the ion beam was neutralized upon the substrate surface; thereafter the lithium tantalate single crystal substrate and the Si substrate were bonded together.

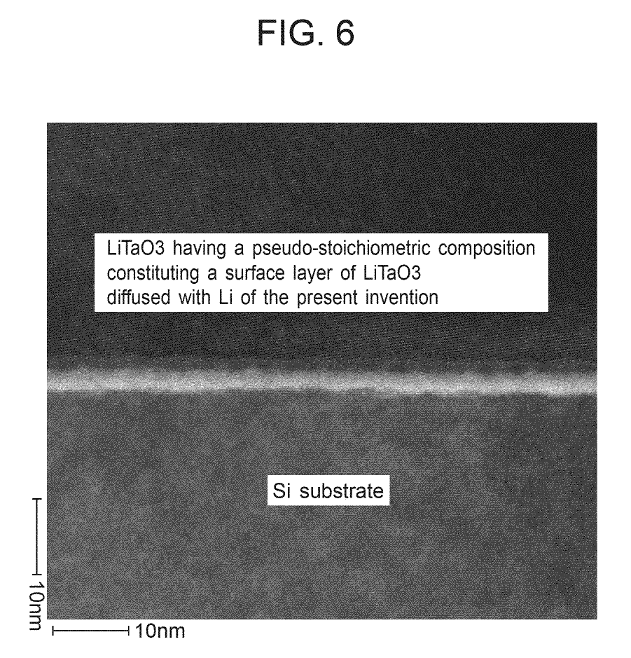

The bonding interface of this bonded substrate was inspected with a transmission electron microscope, and it was observed, as shown in FIG. 6, that the pseudo-stoichiometric composition LiTaO₃ and the atoms of Si at the bonding interface were intermixed with each other to form a firm bonding.

In addition, this bonded substrate consisting of the rotated Y-cut LiTaO₃ substrate diffused with Li and the silicon substrate was lapped and polished on the LiTaO₃ side in a manner such that a LiTaO₃ layer with a thickness of 18 μm as measured from the bonding interface was left, whereupon a bonded substrate of the present invention was finished.

Next, the bonded substrate obtained in this way was evaluated in the same manner as in Example 1, and the results were as shown in Table 2. From these results, it was also confirmed that the bonded substrate of Example 5 also exhibited a large electromechanical coupling coefficient value and a large value Q, and excellent temperature non-dependency characteristic.

### Example 6

In Example 6, first, a lithium tantalate single crystal substrate having a region in which Li concentration is substantially uniform raging from the substrate surface to a depth of 18 μm was prepared by the same method as in Example 1. Next, this substrate and a Si substrate with a thickness of 200 μm were joined by the ordinary temperature bonding method described in the above-mentioned non-IP publication and thus a bonded substrate was obtained.

The bonding interface of this bonded substrate was inspected with a transmission electron microscope, and it was observed like in the case of Example 5 that the pseudo-stoichiometric composition LiTaO₃ and the atoms of Si at the bonding interface were mutually intermixed to form a firm bonding.

In addition, this bonded substrate consisting of the rotated Y-cut LiTaO₃ substrate diffused with Li and the silicon substrate was lapped and polished on the LiTaO₃ side in a manner such that a LiTaO₃ layer with a thickness of 1.2 μm as measured from the bonding interface was left, whereupon a bonded substrate of the present invention was finished.

Next, the bonded substrate obtained in this way was evaluated in the same manner as in Example 1, and the results were as shown in Table 2. From these results, it was also confirmed that the bonded substrate of Example 6 also exhibited a large electromechanical coupling coefficient value and a large value Q, and an excellent temperature non-dependency characteristic.

### COMPARATIVE EXAMPLES

In the comparative examples shown below, lithium tantalate single crystal substrates were prepared by the same method as in Example 1 except that no single polarization treatment was applied to them.

### Comparative Example 1

In Comparative Example 1, during the period of temperature decrease from 770° C. through 500° C. after the Li diffusion treatment, no electric field was applied in an approximate direction of +Z (thus single polarization treatment was not performed), but in other respects, the lithium tantalate single crystal substrate was prepared by the same manner as in Example 1.

It was confirmed that the lithium tantalate single crystal substrate of Comparative Example 1 shows a similar Raman profile as in Example 1, and that the lithium tantalate single crystal substrate has a substantially uniform Li concentration to a depth of 18 μm from the substrate surface.

Next, a small piece was cut out from the Li-diffused 4-inch 42° Y cut lithium tantalate single crystal substrate obtained in Comparative Example 1, and, in a Piezo d33/d15 meter (model ZJ-3BN) manufactured by The Institute of Acoustics of the Chinese Academy of Sciences, the small piece was given a vertical vibration in the thickness direction to the principal face and also to the back face respectively to observe the voltage waveform thereby induced, and the observation indicated an absence of piezoelectric response from every part of the wafer. Hence it was confirmed that the lithium tantalate single crystal substrate of Example 1 does not possess thickness-wise piezoelectricity in every part of the substrate face and that it was not singly polarized.

On the other hand, when this small piece was set in the d15 unit and a vibration was applied in the horizontal direction parallel to the substrate, a piezoelectric response could be picked up in the thickness direction, so that the lithium tantalate single crystal substrate of Comparative Example 1 was found to have turned into an unusual piezoelectric body which exhibits piezoelectricity when it is given a vibration in the horizontal direction parallel to the substrate surface although it does not produce any piezoelectric response in the thickness direction in response to a vibration received in the thickness direction.

The same evaluation as in Example 1 was performed on the lithium tantalate single crystal substrate of Comparative Example 1, and the results are as shown in Table 1. From these results, it was confirmed that, as compared with the 42° Y cut lithium tantalate single crystal substrate not subjected to the Li diffusion treatment, the lithium tantalate single crystal substrate of Comparative Example 1 had a larger electromechanical coupling coefficient k2 and a superior temperature non-dependency characteristic while its values of Q were smaller.

### Comparative Example 2

In Comparative Example 2, first, a lithium tantalate single crystal substrate having a substantially uniform Li concentration in a region ranging from the substrate surface to a depth of 18 μm was prepared by the same method as in Example 1. Next, the surface of this substrate was polished by 8 μm to prepare a lithium tantalate single crystal substrate having a substantially uniform Li concentration to a depth of 10 μm from the substrate surface.

The lithium tantalate single crystal substrate of Comparative Example 2 was evaluated in the same manner as in Example 1, and the results are shown in Table 1. Moreover, when normalized by the wavelength of the leaky surface acoustic wave propagating in the direction X of the wafer, the region in which the Li concentration was uniform ranged from the substrate surface to a depth of 4.0 times the wavelength.

From these results, it was confirmed that, as compared with the 42° Y cut lithium tantalate single crystal substrate not subjected to the Li diffusion treatment, the lithium tantalate single crystal substrate of Comparative Example 2 had a larger electromechanical coupling coefficient k2 and a superior temperature non-dependency characteristic while its values of Q were smaller, as shown by the Q circle curve in FIG. 5.

### Comparative Example 3

In Comparative Example 3, first, a lithium tantalate single crystal substrate having a substantially uniform Li concentration in a region ranging from the substrate surface to a depth of 18 μm was prepared by the same method as in Example 1. Next, the surface of this substrate was polished by 12 μm to prepare a lithium tantalate single crystal substrate having a substantially uniform Li concentration to a depth of 8 μm from the substrate surface.

The lithium tantalate single crystal substrate of Comparative Example 3 was evaluated in the same manner as in Example 1, and the results are shown in Table 1. Moreover, when normalized by the wavelength of the leaky surface acoustic wave propagating in the direction X of the wafer, the region in which the Li concentration was uniform ranged from the substrate surface to a depth of 3.2 times the wavelength.

From these results, it was confirmed that, as compared with the 42° Y cut lithium tantalate single crystal substrate not subjected to the Li diffusion treatment, the lithium tantalate single crystal substrate of Comparative Example 3 had a larger electromechanical coupling coefficient k2 and a superior temperature non-dependency characteristic while its values of Q were smaller.

### Comparative Example 4

In Comparative Example 4, first, a lithium tantalate single crystal substrate having a substantially uniform Li concentration in a region ranging from the substrate surface to a depth of 18 μm was prepared by the same method as in Example 1. Next, the surface of this substrate was polished by 14 μm to prepare a lithium tantalate single crystal substrate having a substantially uniform Li concentration to a depth of 8 μm from the substrate surface.

The lithium tantalate single crystal substrate of Comparative Example 4 was evaluated in the same manner as in Example 1, and the results obtained are shown in Table 1. Furthermore, when normalized by the wavelength of the leaky surface acoustic wave propagating in the direction X of the wafer, the region in which the Li concentration was uniform ranged from the substrate surface to a depth equivalent to 2.4 times the wavelength.

From these results, it was confirmed that, as compared with the 42° Y cut lithium tantalate single crystal substrate not subjected to the Li diffusion treatment, the lithium tantalate single crystal substrate of Comparative Example 3 had a larger electromechanical coupling coefficient k2 and a superior temperature non-dependency characteristic while its values of Q were smaller, as shown by the Q circle curve in FIG. 5.

TABLE 1

| | | Depth from substrate | | | | | | | | | |
|---|---|---|---|---|---|---|---|---|---|---|---|
| | | surface through which Li | | | | | | | | | |
| | | conc. is uniform as | | | | | | | | | |
| | Depth from | normalized in terms of | | | | | | | | | |
| | substrate | times of wavelength of | | | | | | | | | Temperature |
| | surface through | leaky acoustic wave | | | | | | | Anti- | | coefficient of |
| | which Li conc. | propagating in the | | | | | | Resonance | resonance | | resonance |
| | is uniform | LiTaO3 substrate | | | | | | frequency | frequency | k2 | frequency |
| | (μm) | surface (× wavelength) | Qₛ | Qₑ | Qₛ₀ | Qₚ₀ | Q_{ave.} | (MHz) | (MHz) | (%) | (ppm/° C.) |
| Example 1 | 18 | 7.2 | 957 | 1118 | 900 | 500 | 869 | 1658.0 | 1712.0 | 7.7 | −21 |
| Example 2 | 16 | 6.4 | 1070 | 1204 | 600 | 550 | 856 | 1659.0 | 1712.0 | 7.5 | −22 |
| Example 3 | 14 | 5.6 | 957 | 1118 | 900 | 500 | 869 | 1659.0 | 1712.5 | 7.6 | −21 |
| Example 4 | 12.5 | 5.0 | 1020 | 1100 | 750 | 550 | 855 | 1658.0 | 1712.0 | 7.7 | −23 |
| Comparative Example 1 | 18 | 7.2 | 700 | 370 | 274 | 455 | 450 | 1653.0 | 1709.0 | 7.9 | −23 |
| Comparative Example 2 | 10 | 4.0 | 801 | 682 | 750 | 360 | 648 | 1659.0 | 1712.8 | 7.6 | −22 |
| Comparative Example 3 | 8 | 3.2 | 773 | 603 | 600 | 330 | 577 | 1658.0 | 1713.0 | 7.8 | −23 |
| Comparative Example 4 | 6 | 2.4 | 804 | 241 | 150 | 180 | 344 | 1653.5 | 1708.0 | 7.7 | −23 |
| No Li diffusion treatment | — | — | 1106 | 1202 | 500 | 560 | 842 | 1628.0 | 1672.0 | 6.4 | −33 |

TABLE 2

| | | | | | | | | | | Temperature | Temperature |
|---|---|---|---|---|---|---|---|---|---|---|---|
| | Thickness of | | | | | | | Anti- | | coefficient of | coefficient of |
| | LiTaO₃ in | | | | | | Resonance | resonance | | resonance | anti-resonance |
| | bonded | | | | | | frequency | frequency | k2 | frequency | frequency |
| | substrate (μm) | Qₛ | Qₑ | Qₛ₀ | Qₚ₀ | Q_{ave.} | (MHz) | (MHz) | (%) | (ppm/° C.) | (ppm/° C.) |
| Example 5 | 18 | 1535 | 1453 | 1500 | 1150 | 1410 | 1685.0 | 1743.0 | 8.1 | −10 | −20 |
| Example 6 | 12 | 1950 | 1847 | 1700 | 1837 | 1834 | 1724.0 | 1803.0 | 10.5 | 10 | −10 |

### Example 7

In Example 7, first, a lithium tantalate substrate of a 42° rotated Y-cut having a thickness of 300 μm was cut out from a singly polarized 4-inch diameter lithium tantalate (Li:Ta=48.3:51.7) single crystal ingot of a congruent composition. Next, by a lapping process, a surface roughness of the cut out LT substrate became 0.15 μm in terms of arithmetic average roughness (Ra) value, and a thickness of the LT substrate became 250 μm.

Further, both sides of the LT substrate were polished and finished into quasi-mirror surfaces having a surface roughness of 0.01 μm in terms of Ra value. Subsequently, this LT substrate was buried in a powder mainly composed of Li3TaO4 spread in a small container. In this case, as the powder mainly composed of Li3TaO4, a powder obtained by firing a powder, in which Li2CO3 and Ta2O5 were mixed at a molar ratio of Li2CO3:Ta2O5=7:3, at 1300° C. for 12 hours was used.

Next, this small container was set in an electric furnace, and inside of the furnace was set to an N2 atmosphere and was heated at 990° C. for 50 hours to allow Li to diffuse into the LT substrate. After this treatment, one side of the LT substrate was subjected to mirror polishing.

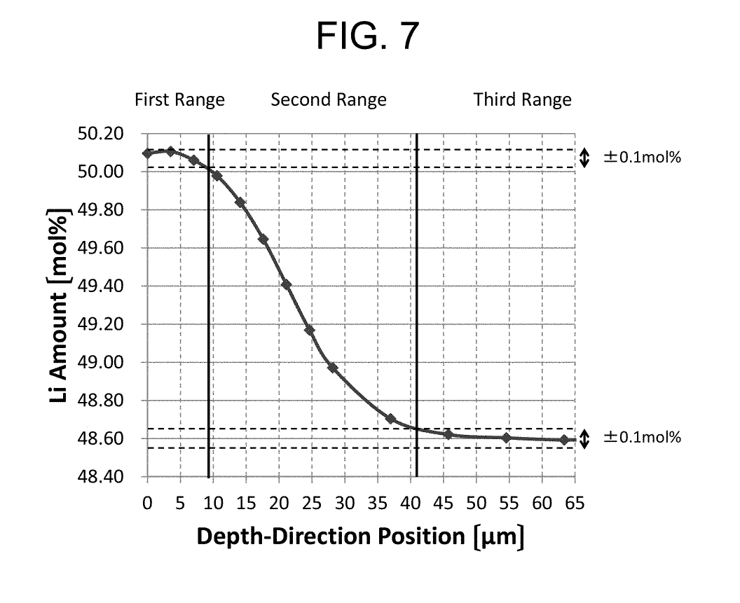

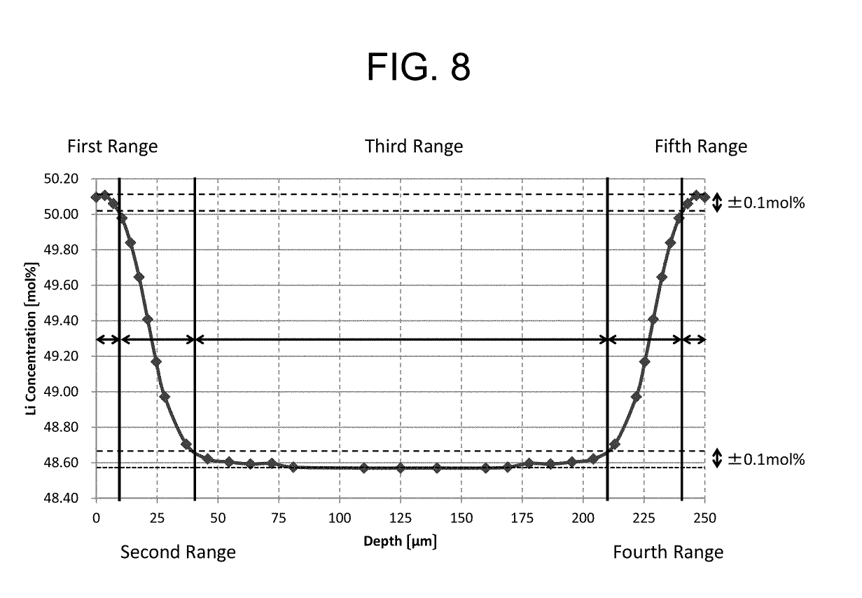

Then, with respect to the LT substrate that had been subjected to the Li diffusion treatment, a half-value width (full width at half maximum) (FWHM1) of a Raman shift peak around 600 cm−1 in a depth direction from a surface was measured using a laser Raman spectrometer. A Li amount was calculated from the measured half-value width using the above Mathematical Formula 1, and profiles of the Li amount in the depth direction illustrated in FIGS. 7 and 8 were obtained.

Measurement was also performed from the other surface, and substantially the same profile of the Li amount in the depth direction was obtained.

From this, it can be seen that the LT substrate was obtained that has a pseudo stoichiometric composition in regions near the surfaces on both sides of the substrate and a congruent composition in an inner part of the substrate.

Next, as a base substrate, a one-side mirror-finished sapphire substrate having a thickness of 500 μm was prepared. Then, it was confirmed that a surface roughness of each of the mirror surfaces of the LT substrate that had been subjected to the Li diffusion treatment and the sapphire substrate was 1.0 nm or less in RMS value.

Subsequently, hydrogen molecular ions were implanted from a mirror surface side of the LT substrate. However, in this case, a dose amount was 9×1016 atm/cm2 and an acceleration voltage was 160 KeV. In this case, a position where the ions were implanted is a position at a depth of 900 nm from the surface, and the Li amount at this position is 50.1 mol %.

The ion-implanted LT substrate and the sapphire substrate were bonded to each other using a room temperature bonding method described in [Takagi H. et. al., “Room-temperature wafer bonding using argon beam activation” From Proceedings-Electrochemical Society (2001), 99-35 (Semiconductor Wafer Bonding: Science, Technology, and Applications V), 265-274].

Specifically, the LT substrate and the sapphire substrate, which had been cleaned, were set in a high-vacuum chamber, and surfaces of the substrates to be bonded were subjected to an activation treatment by being irradiated with fast atomic beams of neutralized argon atoms. Thereafter, the LT substrate and the sapphire substrate were bonded to each other by laminating the LT substrate and the sapphire substrate to each other.

Thereafter, the bonded substrate was heated to 110° C., and a wedge was driven into one end of an ion implantation part of the LT substrate to separate the LT substrate into a LT substrate bonded to the base substrate and a remaining LT substrate.

In this case, the LT substrate had a thickness of 900 nm. However, the surfaces of the LT substrate were polished by 200 nm and the thickness of the LT substrate was set to 700 nm. Further, the maximum height (Rz) of the surface roughness was measured using an atomic force microscope (AFM), and the value was 1 nm.

With respect to the bonded substrate formed from the LT substrate and the sapphire base substrate, observation of voltage waveforms induced by applying vertical vibrations in a thickness direction to a main surface and a back surface was performed using a Piezo d33/d15 meter (model ZJ-3BN) manufactured by the Institute of Acoustics of the Chinese Academy of Sciences, and piezoelectric responses were observed at all sites of the bonded substrate and piezoelectricity was confirmed.

Further, laser Raman spectroscopy was performed on several sites on the LT substrate side surface, and the Li amount was calculated. As a result, the Li amount was 50.0 mol % in all measurement sites, and a uniform pseudo stoichiometric composition was confirmed.

In the LT substrate, the Li amount is reduced by 0.1 mol % at the maximum by the ion implantation.

Next, the surface of the bonded substrate on the LT substrate side was subjected to a sputtering treatment, and an Al film having a thickness of 0.4 μm was formed. Subsequently, a resist was applied, and an electrode pattern of a resonator was exposed and developed using a stepper. Further, electrodes of a SAW device were formed by RIE (Reactive Ion Etching). Here, the resonator was set to have a wavelength of 5 μm.

As a result of measuring various characteristics of the resonator fabricated in this way, a resonance frequency was 921.5 MHz; an anti-resonance frequency was 948.0 MHz; an average sound speed was 4674 m/s; an electromechanical coupling coefficient was 7.5%; a temperature coefficient of the resonance frequency was +5 ppm/° C.; a temperature coefficient of the anti-resonance frequency was −6 ppm/° C.; a resonance Q value was 4200; an anti-resonance Q value was 3500; and a maximum Q value was 10000.

The Q value was obtained from the following Mathematical Formula 4 (see IEEE International Ultrasonics Symposium Proceedings, pages 861-863).

Q(f)=ω*τ(f)*|Γ|(1−|Γ|2) [Mathematical Formula 4]

Here, ω is an angular frequency; τ(f) is a group delay time; and Γ is a reflection coefficient measured using a network analyzer.

Further, the electromechanical coupling coefficient (K2) was obtained from the following Mathematical Formula 5.

K2=(πfr/2fa)/tan(πfr/2fa) [Mathematical Formula 5]

fr: resonance frequency
fa: anti-resonance frequency

Further, values of a resonance load (Qso) and an anti-resonance load (Qpo) were calculated from the following Mathematical Formula 6 based on an MBVD model (see John D. et. al., “Modified Butterworth-Van Dyke Circuit for FBAR Resonators and Automated Measurement System,” IEEE ULTRASONICS SYMPOSIUM, 2000, pages 863-868).

$$Z ( ω ) = \frac{{X}_{p}}{j \cdot ( \frac{ω}{{ω}_{p}} )} \cdot \frac{[ 1 - {( \frac{ω}{{ω}_{s}} )}^{2} + j \cdot ( \frac{ω}{{ω}_{s}} ) \cdot \frac{1}{{Q}_{so}} ]}{[ 1 - {( \frac{ω}{{ω}_{p}} )}^{2} + j \cdot ( \frac{ω}{{ω}_{p}} ) \cdot \frac{1}{{Q}_{po}} ]} \\ \\ r = \frac{{C}_{0}}{{C}_{1}} \\ {ω}_{s} = \frac{1}{\sqrt{{L}_{1} \cdot {C}_{1}}} \\ {( \frac{{ω}_{p}}{{ω}_{s}} )}^{2} = 1 + \frac{1}{r} \\ {X}_{p} = \frac{1}{{ω}_{p} \cdot {C}_{0}} \\ \frac{1}{{Q}_{s}} = {ω}_{s} \cdot {R}_{1} \cdot {C}_{1} \\ \frac{1}{{Q}_{s}} = \frac{{ω}_{s} \cdot {R}_{0} \cdot {C}_{0}}{r} \\ \frac{1}{{Q}_{s 0}} = \frac{1}{{Q}_{s}} \cdot ( 1 + \frac{{R}_{s}}{{R}_{1}} ) \\ \frac{1}{{Q}_{po }} = ( \frac{{ω}_{p}}{{ω}_{s}} ) \cdot ( \frac{1}{{Q}_{s}} + \frac{1}{{Q}_{s}} ) \qquad [ Mathematical Formula 6 ]$$

### Example 8

In Example 8, first, a lithium tantalate substrate of a 42° rotated Y-cut having a thickness of 300 μm was cut out from a singly polarized 4-inch diameter lithium tantalate (Li:Ta=48.3:51.7) single crystal ingot of a congruent composition. Next, by a lapping process, a surface roughness of the cut out LT substrate became 0.15 μm in terms of arithmetic average roughness (Ra) value, and a thickness of the LT substrate became 250 μm.

Further, both sides of the LT substrate were polished and finished into quasi-mirror surfaces having a surface roughness of 0.01 μm in terms of Ra value. Subsequently, this LT substrate was buried in a powder mainly composed of Li3TaO4 spread in a small container. In this case, as the powder mainly composed of Li3TaO4, a powder obtained by firing a powder, in which Li2CO3 and Ta2O5 were mixed at a molar ratio of Li2CO3:Ta2O5=7:3, at 1300° C. for 12 hours was used.

Next, this small container was set in an electric furnace, and inside of the furnace was set to an N2 atmosphere and was heated at 990° C. for 50 hours to allow Li to diffuse into the LT substrate.

Then, with respect to the LT substrate that had been subjected to the Li diffusion treatment, a half-value width (FWHM1) of a Raman shift peak around 600 cm−1 in a depth direction from a surface was measured using a laser Raman spectrometer same as that in Example 7. A Li amount was calculated from the measured half-value width using the above Mathematical Formula 1, and profiles of the Li amount in the depth direction substantially same as those in Example 7 illustrated in FIGS. 7 and 8 were obtained.

Subsequently, hydrogen molecular ions were implanted from a mirror surface side of the LT substrate. However, in this case, a dose amount was 9×1016 atm/cm2 and an acceleration voltage was 160 KeV. In this case, a position where the ions were implanted is a position at a depth of 900 nm from the surface, and the Li amount at this position is 50.1 mol %.

SiO2 was deposited to a thickness of about 10 μm at 35° C. on a surface on the ion-implanted side of the LT substrate using a plasma CVD method. Thereafter, the surface on which SiO2 was deposited was subjected to mirror polishing.

Next, as a base substrate, a one-side mirror-finished Si (SiO2/Si) substrate with a thermal oxide film and having a thickness of 500 m was prepared. Then, it was confirmed that a surface roughness of each of the mirror surfaces of the SiO2/LT substrate and the SiO2/Si substrate was 1.0 nm or less in RMS value.

Next, the SiO2/LT substrate and the SiO2/Si substrate were bonded to each other using a surface activation room temperature bonding method in the same way as in Example 7. Further, in the same way as in Example 7, the LT substrate was separated at the ion implantation part and a surface on the LT substrate side was polished, and a bonded substrate formed from the LT substrate and the Si base substrate was obtained. In the bonded substrate, a SiO2 layer as an interposing layer exists between the piezoelectric substrate and the base substrate.

In this case, the LT substrate had a thickness of 900 nm. However, the surfaces of the LT substrate were polished by 200 nm and the thickness of the LT substrate was set to 700 nm. Further, the maximum height (Rz) of the surface roughness was measured using an atomic force microscope (AFM), and the value was 1 nm. Cracks or the like did not occur in the bonded substrate.

With respect to the bonded substrate thus prepared, in the same way as in Example 7, observation of voltage waveforms induced by applying vertical vibrations in a thickness direction to a main surface and a back surface was performed, and piezoelectric responses were observed at all sites of the bonded substrate and piezoelectricity was confirmed.

Further, in the same way as in Example 7, laser Raman spectroscopy was performed on several sites on the LT substrate side surface, and the Li amount was calculated. As a result, the Li amount was 50.0 mol % in all measurement sites, and a uniform pseudo stoichiometric composition was confirmed.

In the LT substrate, the Li amount is reduced by 0.1 mol % at the maximum by the ion implantation.

Further, with respect to the composite substrate of Example 8, in the same way as in Example 7, electrodes were formed and a resonator was fabricated. This SAW resonator was evaluated in the same way as in Example 7, and substantially the same result as in Example 7 was obtained.

### Comparative Example 5

In Comparative Example 5, first, a singly polarized lithium tantalate single crystal substrate (having a diameter of 4 inches and a thickness of 300 μm, and a 42 rotated Y cut) of a pseudo stoichiometric composition (Li:Ta=49.95:50.05) was prepared. The LT substrate is formed from a single crystal obtained using a double crucible method, and the entire LT substrate has a pseudo stoichiometric composition. One side of the LT substrate was subjected to mirror polishing.

Next, as a base substrate, a one-side mirror-finished sapphire substrate having a thickness of 500 μm was prepared. Then, it was confirmed that a surface roughness of each of the mirror surfaces of the LT substrate that had been subjected to the Li diffusion treatment and the sapphire substrate was 1.0 nm or less in RMS value.

Subsequently, hydrogen molecular ions were implanted from a mirror surface side of the LT substrate. However, in this case, a dose amount was 9×1016 atm/cm2 and an acceleration voltage was 160 KeV. In this case, a position where the ions were implanted is a position at a depth of 900 nm from the surface, and the Li amount at this position is 49.95 mol %.

Next, the ion-implanted LT substrate and the sapphire substrate were bonded to each other using a surface activation room temperature bonding method in the same way as in Example 7. Further, in the same way as in Example 7, the LT substrate was separated at the ion implantation part and a surface on the LT substrate side was polished, and a bonded substrate formed from the LT substrate and the base substrate was obtained.

In this case, the LT substrate had a thickness of 900 nm. However, the surfaces of the LT substrate were polished by 200 nm and the thickness of the LT substrate was set to 700 nm. Further, the maximum height (Rz) of the surface roughness was measured using an atomic force microscope (AFM), and the value was 1 nm. Cracks or the like did not occur in the bonded substrate.

With respect to the bonded substrate thus prepared, in the same way as in Example 7, observation of voltage waveforms induced by applying vertical vibrations in a thickness direction to a main surface and a back surface was performed, and piezoelectric responses were observed at all sites of the bonded substrate and piezoelectricity was confirmed.

Further, in the same way as in Example 7, laser Raman spectroscopy was performed on several sites on the LT substrate side surface, and the Li amount was calculated. As a result, the Li amount was 49.8 mol % in all measurement sites, and a uniform pseudo stoichiometric composition was confirmed.

In the LT substrate, the Li amount is reduced by 0.15 mol % at the maximum by the ion implantation.

Further, with respect to the bonded substrate of Comparative Example 5, in the same way as in Example 7, electrodes were formed and a resonator was fabricated. This SAW resonator was evaluated in the same way as in Example 7, and a result lightly inferior to those of Examples 7 and 8 was obtained.

### Example 9

In Example 9, first, a lithium tantalate substrate of a 42° rotated Y-cut having a thickness of 300 μm was cut out from a singly polarized 4-inch diameter lithium tantalate (Li:Ta=48.3:51.7) single crystal ingot of a congruent composition. Next, by a lapping process, a surface roughness of the cut out LT substrate became 0.15 μm in terms of arithmetic average roughness (Ra) value, and a thickness of the LT substrate became 250 μm.

Further, both sides of the LT substrate were polished and finished into quasi-mirror surfaces having a surface roughness of 0.01 μm in terms of Ra value. Subsequently, this LT substrate was buried in a powder mainly composed of Li3TaO4 spread in a small container. In this case, as the powder mainly composed of Li3TaO4, a powder obtained by firing a powder, in which Li2CO3 and Ta2O5 were mixed at a molar ratio of Li2CO3:Ta2O5=7:3, at 1300° C. for 12 hours was used.

Next, this small container was set in an electric furnace, and inside of the furnace was set to an N2 atmosphere and was heated at 990° C. for 50 hours to allow Li to diffuse into the LT substrate.

Then, with respect to the LT substrate that had been subjected to the Li diffusion treatment, a half-value width (FWHM1) of a Raman shift peak around 600 cm−1 in a depth direction from a surface was measured using a laser Raman spectrometer same as that in Example 7. A Li amount was calculated from the measured half-value width using the above Mathematical Formula 1, and profiles of the Li amount in the depth direction substantially same as those in Example 7 illustrated in FIGS. 7 and 8 were obtained.

The LT substrate was polished by 100 μm from one surface side so as to have a thickness of 150 m. With respect to the LT substrate, laser Raman spectroscopy was performed from the polished side, and a Li amount was calculated in a depth direction from the surface. As a result, in a range from the surface to a depth of 100 μm in the depth direction, the Li amount was 48.6 mol % and a congruent composition was confirmed.

From this, it can be seen that the LT substrate was obtained in which one surface of the substrate has a pseudo stoichiometric composition and the other surface of the substrate has a congruent composition.

Two similar substrates were prepared and were respectively bonded to Si base substrates using a room temperature bonding method. In this case, for one substrate, the surface of a pseudo stoichiometric composition was used as a bonding surface, and for the other substrate, the surface of a congruent composition was used as a bonding surface.

With respect to each of the bonded substrates thus prepared, in the same way as in Example 7, observation of voltage waveforms induced by applying vertical vibrations in a thickness direction to a main surface and a back surface was performed, and piezoelectric responses were observed at all sites of the both bonded substrates and piezoelectricity was confirmed.

### Example 10

In Example 10, first, a lithium tantalate substrate of a 42° rotated Y-cut having a thickness of 300 μm was cut out from a singly polarized 4-inch diameter lithium tantalate (Li:Ta=48.3:51.7) single crystal ingot of a congruent composition. Next, by a lapping process, a surface roughness of the cut out LT substrate became 0.15 μm in terms of arithmetic average roughness (Ra) value, and a thickness of the LT substrate became 250 μm.

Further, both sides of the LT substrate were polished and finished into quasi-mirror surfaces having a surface roughness of 0.01 μm in terms of Ra value. Subsequently, this LT substrate was buried in a powder mainly composed of Li3TaO4 spread in a small container. In this case, as the powder mainly composed of Li3TaO4, a powder obtained by firing a powder, in which Li2CO3 and Ta2O5 were mixed at a molar ratio of Li2CO3:Ta2O5=7:3, at 1300° C. for 12 hours was used.

Next, this small container was set in an electric furnace, and inside of the furnace was set to an N2 atmosphere and was heated at 990° C. for 50 hours to allow Li to diffuse into the LT substrate.

Then, with respect to the LT substrate that had been subjected to the Li diffusion treatment, a half-value width (FWHM1) of a Raman shift peak around 600 cm−1 in a depth direction from a surface was measured using a laser Raman spectrometer same as that in Example 7. A Li amount was calculated from the measured half-value width using the above Mathematical Formula 1, and profiles of the Li amount in the depth direction substantially same as those in Example 7 illustrated in FIGS. 7 and 8 were obtained.

This substrate was bonded to a Si base substrate using a room temperature bonding method. Then, polishing was performed from a surface on the LT substrate side such that the LT substrate had a thickness of 150 μm.

With respect to the bonded substrate, laser Raman spectroscopy was performed from a surface on the LT substrate side, and a Li amount was calculated in a depth direction from the surface. As a result, in a range from the surface to a depth of 100 μm in the depth direction, the Li amount was 48.6 mol % and a congruent composition was confirmed.

From this, it can be seen that the bonded substrate was obtained in which the surface on the LT substrate side has a pseudo stoichiometric composition and the bonding surface has a congruent composition.

With respect to each of the bonded substrates thus prepared, in the same way as in Example 7, observation of voltage waveforms induced by applying vertical vibrations in a thickness direction to a main surface and a back surface was performed, and piezoelectric responses were observed at all sites of the both bonded substrates and piezoelectricity was confirmed.

### Explanation of Designations

A: graph curves (solid line and dotted line) representing Im (Zin) measured values and calculated values in accordance with BVD model in FIG. 4
B: Graph curves (solid line and dotted line) representing Re (Zin) measured values and calculated values in accordance with BVD model in FIG. 4
C: Q circle curves in FIG. 5 representing measured values of the input impedance (Zin) of Example 1 (solid line) and the calculated values in accordance with the BVD model (dotted line)
D: Q circle curves in FIG. 5 representing measured values of input impedance (Zin) in the case of no Li diffusion treatment (solid line) and calculated values in accordance with the BVD model (dotted line)
E: Q circle curves in FIG. 5 representing measured values of the input impedance (Zin) of Comparative Example 2 (in the case wherein the depth of uniform Li concentration region from the substrate surface is 10 μm) (solid line) and the calculated values in accordance with the BVD model (dotted line)
F: Q circle curves in FIG. 5 representing measured values of the input impedance (Zin) of Comparative Example 4 (in the case wherein the depth of uniform Li concentration region from the substrate surface is 6 μm) (solid line) and the calculated values in accordance with the BVD model (dotted line)

Scopes of what is claimed:

1. A method of manufacturing a bonded substrate, comprising:
bonding a base substrate to a LiTaO₃ single crystal substrate which has a concentration profile wherein Li concentration is different between a substrate surface and an inner part of the substrate and wherein Li concentration is substantially uniform in a region ranging from at least one of the substrate's surfaces to a depth; and
removing a LiTaO₃ surface layer opposite the bonding face in a manner such that at least part of said region where the Li concentration is substantially uniform is left.

2. A method of manufacturing a bonded substrate, comprising:
bonding a base substrate to a LiTaO₃ single crystal substrate which has a concentration profile wherein Li concentration is different between a substrate surface and an inner part of the substrate and wherein Li concentration is substantially uniform in a region ranging from at least one of the substrate's surfaces to a depth and
removing a LiTaO₃ surface layer opposite the bonding face in a manner such that only said region where the Li concentration is substantially uniform is left.

3. The method of manufacturing a bonded substrate as claimed in claim 2, wherein that region in which the Li concentration is substantially uniform is of a pseudo-stoichiometric composition.

4. A method for manufacturing a bonded substrate, comprising:
bonding to a base substrate a substrate composed of a Li-containing compound having a concentration profile that shows a difference in Li concentration between a surface of the substrate and an inner part of the substrate; and
removing a surface layer of the substrate composed of a Li-containing compound on an opposite side of a bonding surface such that a portion of the substrate composed of a Li-containing compound remains.

5. The method for manufacturing a bonded substrate according to claim 4, wherein the substrate composed of a Li-containing compound has, in a thickness direction of the substrate:
a first range where a Li concentration is substantially uniform from one surface of the substrate;
a second range where a Li concentration varies from a substrate surface side toward an inner part of the substrate; and
a third range where a Li concentration is substantially uniform, and the first range and the third range have different Li concentrations.

6. The method for manufacturing a bonded substrate according to claim 4, wherein the substrate composed of a Li-containing compound has, in a thickness direction of the substrate:
a first range where a Li concentration is substantially uniform from one surface of the substrate;
a second range where a Li concentration varies from a substrate surface side toward an inner part of the substrate;
a third range where a Li concentration is substantially uniform;
a fourth range where a Li concentration varies from an inner part of the substrate toward the other surface of the substrate; and
a fifth range where a Li concentration is substantially uniform up to the other surface of the substrate, and
the Li concentration of the third range is different from the Li concentrations of the first range and the fifth range.

7. The method for manufacturing a bonded substrate according to claim 5, wherein a range where a Li concentration is substantially uniform is a range of ±0.1 mol %.

8. The method for manufacturing a bonded substrate according to claim 4, wherein, in the substrate composed of a Li-containing compound, a surface of the substrate has a higher Li concentration than an inner part of the substrate.

9. The method for manufacturing a bonded substrate according to claim 4, wherein the substrate composed of a Li-containing compound has a range where, in the thickness direction of the substrate, a substrate surface side has a higher Li concentration.

10. The method for manufacturing a bonded substrate according to claim 4, wherein the portion of the substrate composed of a Li-containing compound remaining in the bonded substrate has a pseudo stoichiometric composition.

11. The method for manufacturing a bonded substrate according to claim 4, wherein the portion of the substrate composed of a Li-containing compound remaining in the bonded substrate has a Li concentration exceeding 50.0 mol %.

12. The method for manufacturing a bonded substrate according to claim 5, wherein the portion of the substrate composed of a Li-containing compound remaining in the bonded substrate includes the first range.

13. The method for manufacturing a bonded substrate according to claim 5, wherein the portion of the substrate composed of a Li-containing compound remaining in the bonded substrate is the first range.

14. The method for manufacturing a bonded substrate according to claim 5, wherein the first range has a pseudo stoichiometric composition.

15. The method for manufacturing a bonded substrate according to claim 5, wherein the first range has a Li concentration exceeding 50.0 mol %.

16. The method for manufacturing a bonded substrate according to claim 5, wherein the third range has a congruent composition.

17. The method for manufacturing a bonded substrate according to claim 6, wherein the portion of the substrate composed of a Li-containing compound remaining in the bonded substrate includes one of the first range and the fifth range.

18. The method for manufacturing a bonded substrate according to claim 6, wherein the portion of the substrate composed of a Li-containing compound remaining in the bonded substrate is one of the first range and the fifth range.

19. The method for manufacturing a bonded substrate according to claim 6, wherein one of the first range and the fifth range has a pseudo stoichiometric composition.

20. The method for manufacturing a bonded substrate according to claim 6, wherein one of the first range and the fifth range has a Li concentration exceeding 50.0 mol %.

21. The method for manufacturing a bonded substrate according to claim 6, wherein the third range has a congruent composition.

22. The method for manufacturing a bonded substrate according to claim 4, wherein the Li-containing compound is one of lithium tantalate and lithium niobate.

23. The method for manufacturing a bonded substrate according to claim 4, wherein the substrate composed of a Li-containing compound is a LiTaO3 single crystal substrate.

24. The method for manufacturing a bonded substrate according to claim 4, wherein the base substrate is any one of Si, SiC, spinel, and sapphire.

25. The method for manufacturing a bonded substrate according to claim 4, wherein an interposing layer is provided between the substrate composed of a Li-containing compound and the base substrate.

26. The method for manufacturing a bonded substrate according to claim 4, wherein, by implanting ions into the substrate composed of a Li-containing compound, a portion to remain as a bonded substrate and a portion to be removed from the bonded substrate are separated from each other.

27. The method for manufacturing a bonded substrate according to claim 26, wherein a Li concentration at a position where the ions are implanted into the substrate composed of a Li-containing compound exceeds 50.0 mol %.

28. The method for manufacturing a bonded substrate according to claim 26, wherein a Li concentration exceeds 50.0 mol % from a surface of the substrate composed of a Li-containing compound on a side where the substrate composed of a Li-containing compound is bonded to the base substrate to the position where the ions are implanted into the substrate composed of a Li-containing compound.

29. A bonded substrate, comprising:
a substrate composed of a Li-containing compound; and
a base substrate,
wherein a Li concentration of a surface on a side of the substrate composed of a Li-containing compound exceeds 50.0 mol %.

30. The bonded substrate according to claim 29, wherein a Li concentration of the substrate composed of a Li-containing compound exceeds 50.0 mol %.

31. A bonded substrate, comprising:
a substrate composed of a Li-containing compound; and
a base substrate,
wherein a Li concentration of a surface on a side of the substrate composed of a Li-containing compound exceeds 49.9 mol %,
the substrate composed of a Li-containing compound has a thickness of 1.0 μm or less, and
a maximum height (Rz) value of a surface roughness on the side of the substrate composed of a Li-containing compound is 10% or less of the thickness of the substrate composed of a Li-containing compound.

32. The bonded substrate according to claim 31, wherein a Li concentration of the substrate composed of a Li-containing compound exceeds 49.9 mol %.

33. The bonded substrate according to claim 31, wherein the Li-containing compound is one of lithium tantalate and lithium niobate.

34. The bonded substrate according to claim 31, wherein the substrate composed of a Li-containing compound is a LiTaO3 single crystal substrate.

35. The bonded substrate according to claim 31, wherein the base substrate is any one of Si, SiC, spinel, and sapphire.

36. The bonded substrate according to claim 31, wherein an interposing layer is provided between the substrate composed of a Li-containing compound and the base substrate.

37. A substrate composed of a Li-containing compound wherein one surface of the substrate and the other surface of the substrate have different Li concentrations.

38. A substrate composed of a Li-containing compound comprising, in a thickness direction of the substrate:
a first range where a Li concentration is substantially uniform from a bonding surface;
a second range where a Li concentration varies from the bonding surface side toward a surface on an opposite side of the bonding surface; and
a third range where a Li concentration is substantially uniform up to the surface on the opposite side of the bonding surface.

39. A method for manufacturing the substrate composed of a Li-containing compound according to claim 38, comprising:
removing a portion of a substrate which is composed of a Li-containing compound and has a concentration profile that shows a difference in Li concentration between a surface of the substrate and an inner part of the substrate, the removing being conducted such that an inner part of the substrate having a Li concentration different from that of a surface of the substrate becomes a surface of the substrate on one side.

40. A method for manufacturing the substrate composed of a Li-containing compound according to claim 38, comprising:
removing a portion of a substrate which is composed of a Li-containing compound and has, in a thickness direction of the substrate:
a first range where a Li concentration is substantially uniform from one surface of the substrate;
a second range where a Li concentration varies from a substrate surface side toward an inner part of the substrate;
a third range where a Li concentration is substantially uniform;
a fourth range where a Li concentration varies from an inner part of the substrate toward the other surface of the substrate; and
a fifth range where a Li concentration is substantially uniform up to the other surface of the substrate, such that the Li concentration of the third range is different from the Li concentrations of the first range and the fifth range,
wherein the removing is conducted such that an inner part of the third range becomes a surface of the substrate on one side.

41. A method for manufacturing a bonded substrate, comprising:
bonding to a base substrate the substrate composed of a Li-containing compound according to claim 38.

42. A bonded substrate, comprising:
a substrate composed of a Li-containing compound; and
a base substrate,
wherein a Li concentration of a surface of the bonded substrate on a side of the substrate composed of a Li-containing compound is different from a Li concentration of a bonding surface of the substrate composed of a Li-containing compound.

43. The bonded substrate according to claim 42, wherein the bonding surface of the substrate composed of a Li-containing compound has a higher Li concentration than the surface of the bonded substrate on the side of the substrate composed of a Li-containing compound.

44. The bonded substrate according to claim 42, wherein the surface of the bonded substrate on the side of the substrate composed of a Li-containing compound has a higher Li concentration than the bonding surface of the substrate composed of a Li-containing compound.

45. The bonded substrate according to claim 42, wherein one of the surface of the bonded substrate on the side of the substrate composed of a Li-containing compound and the bonding surface of the substrate composed of a Li-containing compound has a pseudo stoichiometric composition.

46. The bonded substrate according to claim 42, wherein the Li-containing compound is one of lithium tantalate and lithium niobate.

47. The bonded substrate according to claim 42, wherein the substrate composed of a Li-containing compound is a LiTaO3 single crystal substrate.

48. The bonded substrate according to claim 42, wherein the base substrate is any one of Si, SiC, spinel, and sapphire.

49. The bonded substrate according to claim 42, wherein an interposing layer exists between the substrate composed of a Li-containing compound and the base substrate.

50. A bonded substrate, comprising:
a substrate composed of a Li-containing compound; and
a base substrate,
wherein the substrate composed of a Li-containing compound includes, in a thickness direction of the substrate:
a first range where a Li concentration is substantially uniform from a bonding surface;
a second range where a Li concentration varies from the bonding surface side toward a surface on an opposite side of the bonding surface; and
a third range where a Li concentration is substantially uniform up to the surface on the opposite side of the bonding surface.

51. The bonded substrate according to claim 50, wherein a range where a Li concentration is substantially uniform is a range of ±0.1 mol %.

52. The bonded substrate according to claim 50, wherein the first range and the third range have different Li concentrations.

53. The bonded substrate according to claim 50, wherein the third range has a higher Li concentration than the first range.

54. The bonded substrate according to claim 50, wherein the first range has a higher Li concentration than the third range.

55. The bonded substrate according to claim 50, wherein one of the first range and the third range has a pseudo stoichiometric composition.
